(19) United States
(12) Patent Application Publication
(10) Pub. No.: US 2009/0082981 A1
(43) Pub. Date: Mar. 26, 2009

(54) METHOD AND APPARATUS FOR MEASUREMENT OF AMPLITUDE OF PERIODIC SIGNAL AND METHOD AND APPARATUS FOR TEST OF MAGNETIC HEAD

(75) Inventor: Akifumi MUTO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/185,913

(22) Filed: Aug. 5, 2008

(30) Foreign Application Priority Data
Sep. 20, 2007 (JP) 2007-244434

(51) Int. Cl. G01R 23/16

(52) U.S. Cl. 702/77

(57) ABSTRACT

A method for measurement of amplitude of a periodic signal which is noise-robust, free of the effects of leakage of the frequency component, and free of any unbalance between the + side amplitude and − side amplitude, comprising (i) converting a periodic signal to a digital signal, (ii) applying a discrete Fourier transform to this digital periodic signal, calculating the magnitudes and phases of a fundamental frequency component and harmonic frequency components of the periodic signal in the frequency domain, (iii) applying an inverse discrete Fourier transform to the calculated frequency components to reconstruct the waveform in the time domain, and (iv) measuring the amplitude of the periodic signal from the waveform data at the center part of the reconstructed waveform on the time axis.

### BACKGROUND OF THE INVENTION

1. Field of the Invention

The present invention relates to a method and apparatus for measurement of the amplitude of a periodic signal or other signal which periodically repeats a certain waveform. Further, it relates to a method and apparatus for test of a magnetic head using such a method and apparatus.

2. Description of the Related Art

In the field of signal measurement, periodic signals which repeat the same waveforms at a certain period are frequently measured for average values of the + side amplitude and − side amplitude of the periodic signals.

As one example, there is the test for evaluation of the characteristics of magnetic heads in the field of measurement of signals of magnetic heads. One of the test items is to measure the average magnitudes of the + side amplitude and − side amplitude of the read back signal output from a magnetic head when repeating magnetic transitions at a certain period. Further, the waveform of the read back signal is evaluated for symmetry (allowable) and asymmetry (not allowable) with the baseline.

Alternatively, Japanese Patent Publication (A) No. 2004-151065 discloses the field of signal measurement measuring and displaying the waveform of a high frequency signal of integrated circuits operating at several GHz. The present invention can of course be applied to such a signal measurement field.

FIG. 18 is a view showing an example of a waveform of a periodic signal. The waveform of the periodic signal in this figure is the ideal waveform of the read back signal output from a magnetic head when repeating magnetic transitions at a certain period in the above-mentioned test for evaluation of the characteristics of a magnetic head. That is, this is a waveform where the + side amplitude A+ from the baseline of the waveform W to the + side peak and the − side amplitude A− from the baseline to the − side peak are the same in magnitude and which therefore satisfies the requirement for symmetry. If the magnitude of the + side amplitude A+ and the magnitude of the − side amplitude A− differs, the waveform becomes asymmetric, so this is not preferable. This situation is shown in the next figure.

FIG. 19A is a view showing an example of a waveform of a periodic signal with poor symmetry, while FIG. 19B is a view showing an example of a waveform with good symmetry. The former waveform is shown by W, while the latter waveform is shown by W′.

That is, these show examples of read back signals from actual magnetic heads. The waveforms of these figures show read back signals when repeating NRZI data {1,0,0,0,0,0,0,0} and repeating + and − transitions at 8T intervals where the magnetic transition is “1” and the period of the maximum write frequency is “T”. FIG. 19A shows the case where the symmetry is poor (asymmetric), while FIG. 19B shows the case where the symmetry is relatively good (symmetric). Asymmetry of the + side amplitude and the − side amplitude is not preferable as a characteristic of a magnetic head. In tests of magnetic heads, the averages of the + side amplitude and − side amplitude are measured and the asymmetry is calculated from these values as one of the test items.

The + and − amplitudes of the actual read back signal vary depending on noise and other effects, so when measuring and evaluating the characteristics of a magnetic head, the averages of the + side amplitude and − side amplitude in a certain predetermined period are measured and the degree of asymmetry is found from these averages. Not only in the case of measuring and evaluating the amplitude characteristics of a magnetic head, but also in the general signal measurement field, the average + and − amplitudes of a periodic signal are measured in various circumstances.

Measurement of the amplitude of a periodic signal, in particular the + side amplitude and the − side amplitude, is important in the field of signal measurement. Note that in the following explanation, “symmetry” and “asymmetry” will be referred to often, but they themselves are not important to the present − invention. The important thing is measurement of the magnitude of the amplitude of a periodic signal, in particular the + side amplitude and − side amplitude themselves.

Therefore, a conventional example of a method (apparatus) for measurement of the amplitude and a known method (apparatus) disclosed in the above patent publication will be described in detail below.

FIG. 20 is a view showing a conventional example of a circuit for measuring the amplitude of a periodic signal, while FIG. 21 is a view showing the signal waveform in the circuit of FIG. 20. The circuit of FIG. 20 is a so-called envelope tracking circuit.

In the configuration of FIG. 20, two systems of comparators, up/down control circuits, and integrators corresponding to the + and − sides are used to generate + side and − side envelope signals (FIG. 21) corresponding to the amplitudes of the peak points of the periodic signals in these systems. Now, if the voltage value of the + side envelope signal is smaller than the voltage value of the input periodic signal (read back signal), the + side voltage comparator turns on and a + direction pulse is output from the up/down control circuit. This + direction pulse is integrated by the integrator, which operates in a direction increasing the voltage value of the + side envelope signal.

Conversely when the voltage value of the + side envelope signal is larger than the voltage value of the input periodic signal, the + side voltage comparator turns off and a − direction pulse is output from the up/down control circuit. This output is integrated by the integrator, which operates in a direction decreasing the voltage value of the + side envelope signal.

As a result, the + side envelope signal operates so as to track the voltage of the + side peak point of the input periodic signal. The same is true for the − side envelope signal. The data of the + side amplitude and − side amplitude of the thus obtained input periodic signal may if necessary be summed and averaged, a predetermined number of times, to find the values of the average + side amplitude and − side amplitude. These values are converted to digital values by the AD converter (ADC) to obtain + side amplitude data and − side amplitude data.

Note that instead of the above comparators, a configuration using peak hold circuits is also well known.

The method shown in the above FIG. 20 and FIG. 21 is a method which measures the time domain parameters, that is, the + side amplitude and − side amplitude of a signal, in the same time domain. As opposed to this, there is a method by taking note that the signal is a periodic signal, which calculates the magnitudes and phase relationship of the fundamental frequency component and harmonic frequency components in the frequency domain and applies an inverse transform to the above relationship into the time domain to reconstruct the signal waveform. This is the method disclosed in the above patent publication.

FIG. 22 is a view showing the apparatus disclosed in the patent publication and shows the principle of measurement of a periodic signal by this publication. This method provides two systems of heterodyne mixing (a, b/c, d), an AD converter (e/f), and a Fourier transform system (g, h), uses one system among these two systems as a reference for measurement of the frequency component of the fundamental or fixed harmonic frequency component, uses the other system for measurement of the n-th harmonic component, applies a Fourier transform to the two systems to find the magnitudes and phase differences of the components, inversely transforms these to the time domain, and thereby reconstruct the waveform of the original periodic signal and finally measures the waveform.

In this regard, the above-mentioned prior art example (FIG. 20 and FIG. 21) and known example (FIG. 22) have the following problems.

First, the method using the time domain of the prior art example (FIG. 20 and FIG. 21) uses voltage comparators or peak hold circuits, so when high frequency noise is superposed on the + peak part and − peak part of the input periodic signal or when low frequency noise is superposed on the input periodic signal as a whole, there are the problems that an erroneous amplitude far from the original amplitude is measured and thus the results are affected by noise etc.

Further, voltage comparators and peak detectors have limits as to the minimum detectable pulse widths. If the frequency of the input periodic signal becomes higher and the pulse width becomes finer, there is the problem that the measured peak level tends to become lower than the actual peak level to be measured.

Still further, the + side circuits and the − side circuits are independent, so it is difficult to match the characteristics of these two circuits. Therefore, there is the problem that unbalance easily occurs between the + side and − side measured amplitudes and a polarity difference ends up occurring in the measurement results.

On the other hand, the method of the above patent publication (FIG. 22) utilizes the property of the input signal being a periodic signal. By utilizing the property, the method reconstructs the waveform of the original frequency signal by using the magnitudes of the fundamental frequency component and harmonic frequency components of the frequency domain and also the phase relationship between these, so as to measure the amplitude to be obtained. On this point, the above method is common with the method of the present invention explained later. However, as explained above, since two systems of signal processing system are provided and one of the two systems is used as a reference at all times, there is the problem that the circuit becomes larger. Further, the measurement is achieved by using the same clock signal for the clock signals of the AD converters of the two systems, using one of the two systems for measurement of the reference component at all times, and measuring the n-th component in the other system, so as to find the phase difference between these components. However, if the phase difference occurring due to the local oscillation signals (a, c) of the mixers of one system and the other system is not determined, the phase relationship between the original harmonic frequency components and the fundamental frequency component cannot actually be determined. Furthermore, it is difficult to generate these local oscillation signals by a predetermined fixed phase relationship at all times while changing the frequency depending on the order of the harmonic being measured. Further again, the frequency of the periodic signal being measured and the sampling frequencies of the AD converters (e, f) generally are not in relationships of whole multiples, so in this case the discrete frequency of the Fourier transform (g) and frequencies of the fundamental and harmonic frequency components do not match. Therefore, there are the problems that the phenomena of leakage of the frequency components etc. occur, the power ends up being dispersed among a plurality of discrete frequencies, and the amplitudes of the components become different from the inherent values.

### SUMMARY OF THE INVENTION

Therefore, the present invention, in consideration of the above problems, has, as its object, the provision of a method and apparatus for measurement of amplitude of a periodic signal that is noise-robust, free of any unbalance between the + side amplitude measurement system and − side amplitude measurement system, and free of the effects of leakage of the frequency component. Further, it has, as its object, the provision of a method and apparatus for test of a magnetic head free from the above problems. To attain the above first object, the method of the present invention comprises converting a periodic signal to a digital signal (S11), applying a discrete Fourier transform to this digital periodic signal, calculating the magnitudes and phases of a fundamental frequency component and harmonic frequency components of the periodic signal in the frequency domain (S12), applying an inverse discrete Fourier transform to the calculated frequency component values so as to reconstruct the waveform in the time domain (S13), and measuring the amplitude of the periodic signal from the waveform data at the center part of the reconstructed waveform on the time axis (S14).

### BRIEF DESCRIPTION OF THE DRAWINGS

These and other objects and features of the present invention will become clearer from the following description of the preferred embodiments given with reference to the attached drawings, wherein:

FIG. 1 is a flow chart showing a method for measurement of amplitude according to a first embodiment,

FIG. 2A is a flow chart showing a method for measurement of amplitude according to a second embodiment,

FIG. 3 is a view showing an apparatus for measurement of amplitude according to a first embodiment,

FIG. 4 is a view showing an apparatus for measurement of amplitude according to a second embodiment,

FIG. 5 is a first part of a view showing a flow of processing according to the present invention,

FIG. 6 is a second part of a view showing a flow of processing according to the present invention,

FIGS. 7A and 7B are views showing asymmetry and symmetry of examples regarding waveforms of actual read back signals from magnetic heads;

FIG. 8A is a view showing a waveform the same as FIG. 7A, while FIG. 8B is a view showing a waveform of this waveform multiplied with a window function,

FIG. 9A is a view of the amplitude of the results when applying a discrete Fourier transform to the waveform of FIG. 8B, while FIG. 9B is a view showing the phase,

FIG. 10 is a view showing only the FFT frequency components corresponding to fundamental and harmonic frequencies,

FIG. 11 is a view showing the frequency domain waveform of FIG. 10 converted back to the time domain waveform,

FIG. 12 is a view showing enlarged part of a head part shown in FIG. 11,

FIG. 13 is a view showing enlarged part of a center part shown in FIG. 11,

FIG. 14 is a first part of a view showing the relationship between the orders of harmonics and a reconstructed waveform,

FIG. 15 is a second part of a view showing the relationship between the orders of harmonics and a reconstructed waveform,

FIG. 16A is a view showing that the higher the order, the closer to the saturation level at the + amplitude side, FIG. 16C at the − amplitude side, and FIG. 16B a ratio of the two,

FIG. 17 is a view showing a reconstructed waveform when reconstructing a waveform using the harmonic components up to the seventh order,

FIG. 18 is a view showing an example of the waveform of a periodic signal,

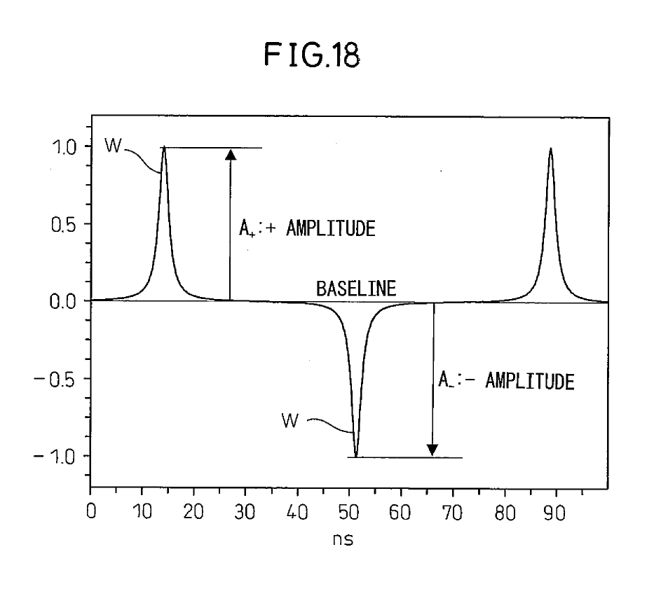

FIG. 19A is a view showing an example of a symmetric waveform of a periodic signal, while FIG. 19B is a view showing an example of an asymmetric waveform,

FIG. 20 is a view showing a conventional example of a circuit for measurement of the amplitude of a periodic signal,

FIG. 21 is a view showing a signal waveform in the circuit of FIG. 20,

FIG. 22 is a view showing an apparatus disclosed in the Japanese patent publication,

FIG. 23 is a first part of a view showing the overall configuration of an apparatus for measurement of amplitude by DFT/IDFT,

FIG. 24 is a second part of a view showing the overall configuration of an apparatus for measurement of amplitude by DFT/IDFT,

FIG. 25 is a third part of a view showing the overall configuration of an apparatus for measurement of amplitude by DFT/IDFT,

FIG. 26 is a view showing details of a window coefficient processing unit 46 of FIG. 24,

FIG. 27 is a view showing details of a DFT/IDFT amplitude measurement unit of FIG. 24,

FIG. 28 is a view showing the details of a DFT unit 55 of FIG. 27,

FIG. 29 is a first part of a view showing details of a DFT (n-th harmonic) unit 61 of FIG. 28,

FIG. 30 is a second part of a view showing details of a DFT (n-th harmonic) unit 61 of FIG. 28,

FIG. 31 is a first part of a view showing details of a DFT phase address generation unit 62 of FIG. 29,

FIG. 32 is a second part of a view showing details of a DFT phase address generation unit 62 of FIG. 29,

FIG. 33 is a view showing details of DFT coefficient generation units 63 and 64 of FIG. 29,

FIG. 34 is a view showing details of a DFT multiplication and accumulation (MAC) operation unit 65 of FIG. 30,

FIG. 35 is a view showing details of an IDFT unit 56 of FIG. 27,

FIG. 36 is a first part of a view showing details of an IDFT (n-th harmonic) unit 73 of FIG. 35,

FIG. 37 is a second part of a view showing details of an IDFT (n-th harmonic) unit 73 of FIG. 35,

FIG. 38 is a first part of a view showing details of an IDFT time phase address generation unit 75 of FIG. 36,

FIG. 39 is a second part of a view showing details of an IDFT time phase address generation unit 75 of FIG. 36,

FIG. 40 is a third part of a view showing details of an IDFT time phase address generation unit 75 of FIG. 36,

FIG. 41 is a view showing details of IDFT coefficient generation units 76 and 77 of FIG. 36.

FIG. 42 is a view showing details of an IDFT component adder 57 of FIG. 27,

FIG. 43 is a first part of a view showing details of an amplitude measurement unit 58 of FIG. 27,

FIG. 44 is a second part of a view showing details of an amplitude measurement unit 58 of FIG. 27, and

FIG. 45 is a third part of a view showing details of an amplitude measurement unit 58 of FIG. 27.

### DESCRIPTION OF THE PREFERRED EMBODIMENTS

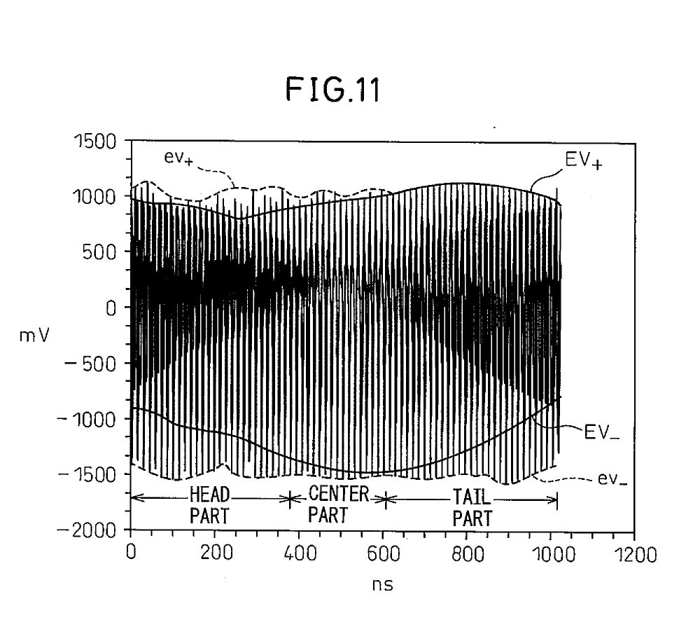

Preferred embodiments of the present invention will be described in detail below while referring to the attached figures. The method according to a first embodiment of the present invention has the following steps (i) to (iv): (i) a step of converting a periodic signal repeating a certain waveform periodically to a digital signal, (ii) a step of applying a discrete Fourier transform to this digital periodic signal and calculating the magnitudes and phases of a fundamental frequency component and harmonic frequency components of the periodic signal in the frequency domain, (iii) a step of applying an inverse discrete Fourier transform to the frequency components to reconstruct the waveform in the time domain, and (iv) a step of measuring the amplitude of the periodic signal from the waveform data at the center part of the reconstructed waveform on the time axis (see “center part” of FIG. 11).

Further, the specific method according to the second embodiment has the following steps (i) to (v): (i) a step of inputting a periodic signal repeating a certain waveform periodically, (ii) a step of applying a discrete Fourier transform to the input periodic signal and setting the closest discrete frequencies to the frequencies of a fundamental frequency component and harmonic frequency components of the periodic signal in the discrete frequency domain, (iii) a step of calculating a fundamental frequency component and harmonic frequency components corresponding to the set discrete frequencies, (iv) a step of applying an inverse discrete Fourier transform to the calculated fundamental frequency component and harmonic frequency components to reconstruct the waveform of the time domain, and (v) calculating the maximum value and minimum value of the waveform based on the waveform data at the center the part of the reconstructed waveform in the time domain (see “center part” of FIG. 11) and outputting the + side amplitude and − side amplitude of the periodic signal to be measured from the calculated maximum and minimum values.

The apparatus according to the first embodiment of the present invention is comprised of the following functional units (i) to (iv): (i) an AD conversion unit converting a periodic signal repeating a certain waveform periodically to a digital signal, (ii) a discrete Fourier transform unit calculating the magnitudes and phases of fundamental and harmonic frequency components of the digital periodic signal in the frequency domain, (iii) an inverse discrete Fourier transform unit applying an inverse discrete Fourier transform to the frequency components and summing the results to reconstruct the waveform in the time domain, and (iv) an amplitude calculation unit calculating the amplitude of the periodic signal from the waveform data at the center part of the reconstructed waveform on the time axis.

Further, the specific apparatus according to the second embodiment is comprised of the following functional units (i) to (v): (i) an input unit inputting a periodic signal repeating a certain waveform periodically, (ii) a frequency setting unit setting the closest discrete frequencies to the frequencies of fundamental and harmonic frequency components of the periodic signal in the discrete frequency domain, (iii) a discrete Fourier transform unit which calculates fundamental and harmonic frequency components corresponding to the set discrete frequencies by a discrete Fourier transform, (iv) an inverse Fourier transform unit applying an inverse Fourier transform to the frequency components and adding the results to reconstruct the waveform of the time domain, and (v) an amplitude calculation unit calculating the amplitude of the periodic signal based on the waveform data at the center part on the time axis.

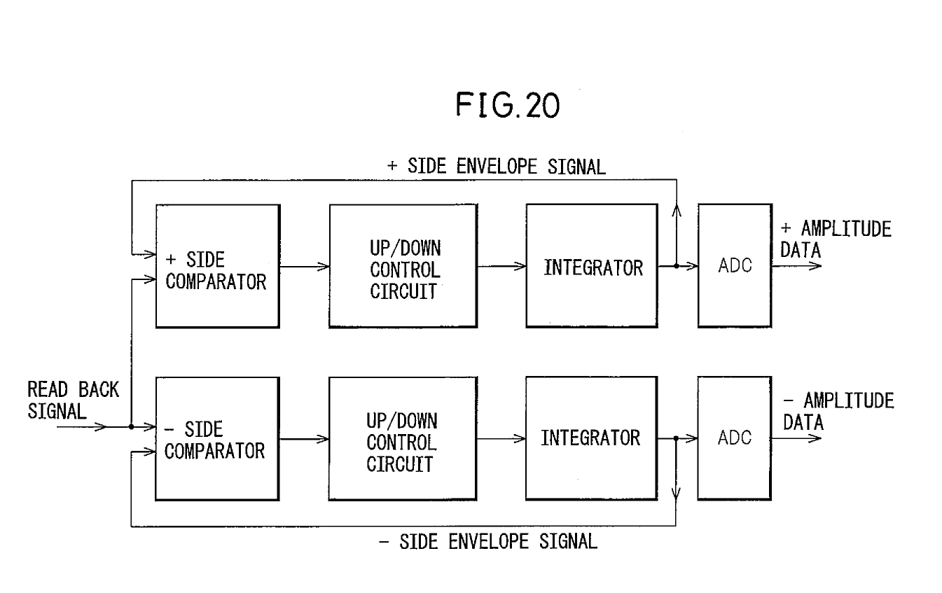

According to the present invention, the values of the frequency components required in the frequency domain are found and the average amplitude of the input periodic signal of the final value in the time domain is found from the above found values, so this method is very noise-robust. Further, it is possible to find the + side amplitude and − side amplitude precisely without the occurrence of the unbalance between the + side amplitude measurement system and the − side amplitude measurement system, which unbalance is seen in the measurement circuit in the time domain according to the prior art (FIG. 20).

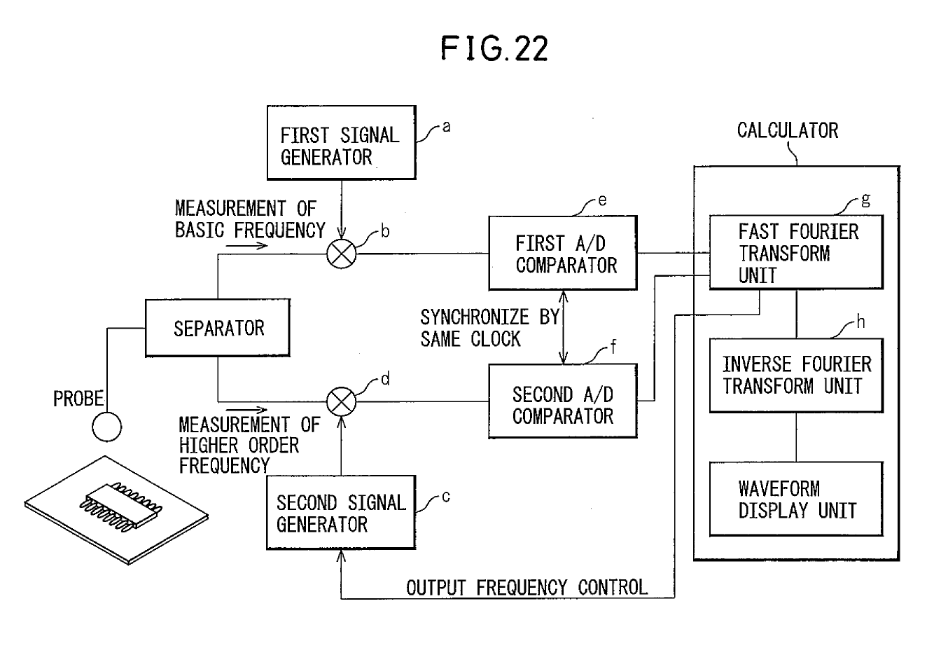

Further, if compared with the above known example (FIG. 22), no matter what value the frequency of the input periodic signal is, highly precise measurement becomes possible and can be realized by a small circuit size without the effects of leakage of the frequency component as already explained (that is, the measured amplitude value becomes smaller than actual due to the deviation between the actual frequencies of the fundamental and harmonic frequency components of the input periodic signal in the frequency domain and the frequencies of the discrete BIN frequencies in the discrete frequency domain).

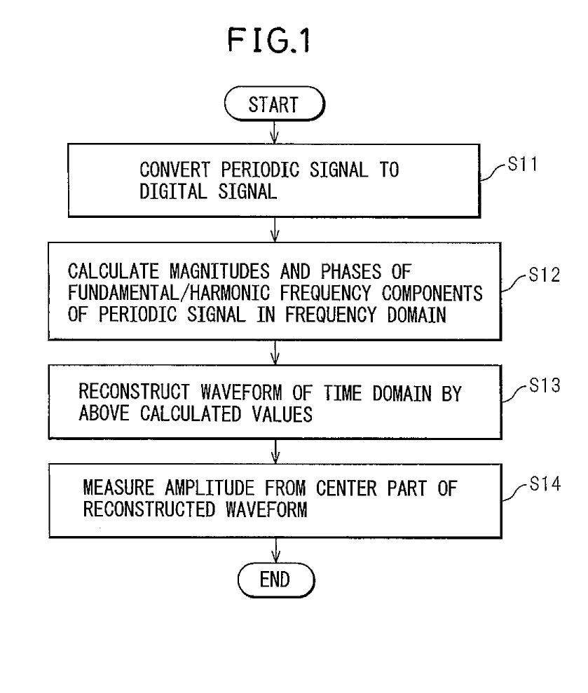

FIG. 1 is a flow chart showing the method of measurement of amplitude according to the first embodiment. In the figure, the method comprises:

Step S11: converting a periodic signal repeating a certain waveform periodically to a digital signal,

Step S12: applying a discrete Fourier transform to the digital periodic signal and calculating the magnitudes and phases of fundamental and harmonic frequency components of the periodic signal in the frequency domain,

Step S13: applying an inverse discrete Fourier transform to the value of the frequency components and summing the results to reconstruct the waveform in the time domain, and

Step S14: measuring the amplitude of the periodic signal from the waveform data at the center part of the reconstructed waveform (center part) on the time axis.

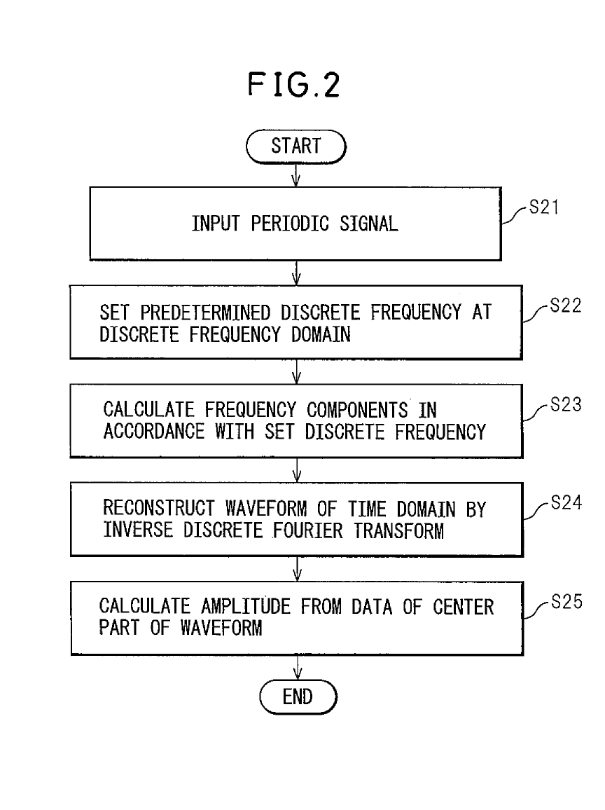

FIG. 2 is a flow chart showing the method of measurement of amplitude according to a second embodiment. In the figure, the method comprises:

Step S21: inputting a periodic signal to be measured repeating a certain waveform periodically,

Step S22: setting the closest discrete frequencies to the frequencies of fundamental and harmonic frequency components of the periodic signal in the discrete frequency domain,

Step S23: applying a discrete Fourier transform to the fundamental frequency component and harmonic frequency components corresponding to the set discrete frequencies to calculate the frequency components,

Step S24: applying an inverse discrete Fourier transform to the values of the frequency components of the calculated fundamental and harmonic frequency components and summing the results to reconstruct the waveform of the time domain, and

Step S25: calculating the maximum value and minimum value of the waveform based on the waveform data at the center part of the reconstructed waveform in the time domain (center part) and outputting the + side amplitude and − side amplitude of the periodic signal to be measured from the resultant calculated values.

More preferable aspects of the above steps are as follows: That is, step S21 of inputting the periodic signal includes the step of converting an analog periodic signal to a digital periodic signal, while the following steps S22 to S25 are performed by digital processing.

Before step S22 of applying a discrete Fourier transform, processing is performed for multiplying a window function with a digitally converted periodic signal.

At step S25 of calculating the maximum value and minimum value, the part positioned at the center is defined as the time-wise center part of the waveform corresponding to one period's worth of the input signal when substantially equally dividing the reconstructed time domain waveform into a head part, center part, and tail part.

The harmonic frequency components are the n-th harmonics (n being an integer greater than or equal to 2) whose frequencies are multiples of the fundamental frequency. Step S24 of reconstructing the time domain waveform adds the frequency components up to a predetermined n-th harmonic to the fundamental frequency component. In this case, the order of the harmonic is determined using the value of “n” where the error between the waveform of the periodic signal and the waveform of the time domain reconstructed converges to substantially zero, when increasing “n”.

The above-mentioned method of measurement of amplitude of the periodic signal can for example be applied to the method of testing a magnetic head. The method of measurement of amplitude of the periodic signal described in FIG. 1 or FIG. 2 is used to measure the + side amplitude and − side amplitude of the periodic read back signal from a magnetic head, which is a part of the evaluation of characteristics of magnetic heads. Further, it judges the symmetry or asymmetry of the periodic read back signal from the magnitudes of the + side amplitude and − side amplitude.

Next, examples of apparatuses for working the above methods of measurement of amplitude of a periodic signal will be explained.

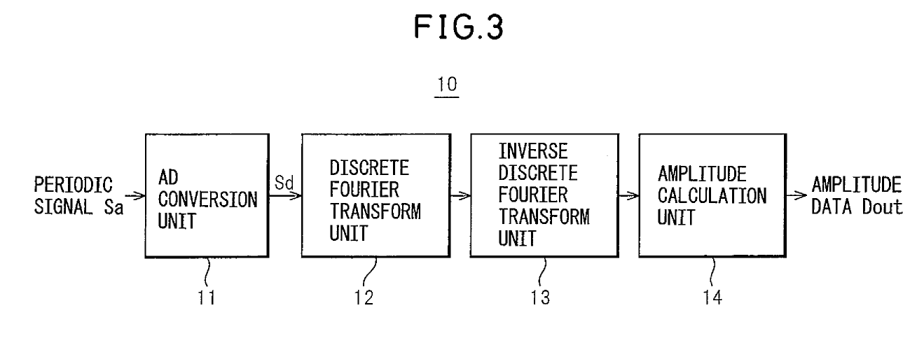

FIG. 3 is a view showing an apparatus for measurement of amplitude according to a first embodiment. In the figure, the apparatus 10 is comprised of the illustrated four functional units 11, 12, 13, and 14, that is, an AD conversion unit 11 converting a periodic signal Sa repeating a certain waveform periodically to a digital signal, a discrete Fourier transform unit 12 calculating the magnitudes and phases of fundamental and harmonic frequency components of the digital periodic signal Sd in the frequency domain, an inverse discrete Fourier transform unit 13 applying an inverse discrete Fourier transform to the frequency components and summing the results to reconstruct the waveform in the time domain, and an amplitude calculation unit 14 calculating the amplitude of the periodic signal Sa from the waveform data at the center part of the reconstructed waveform on the time axis.

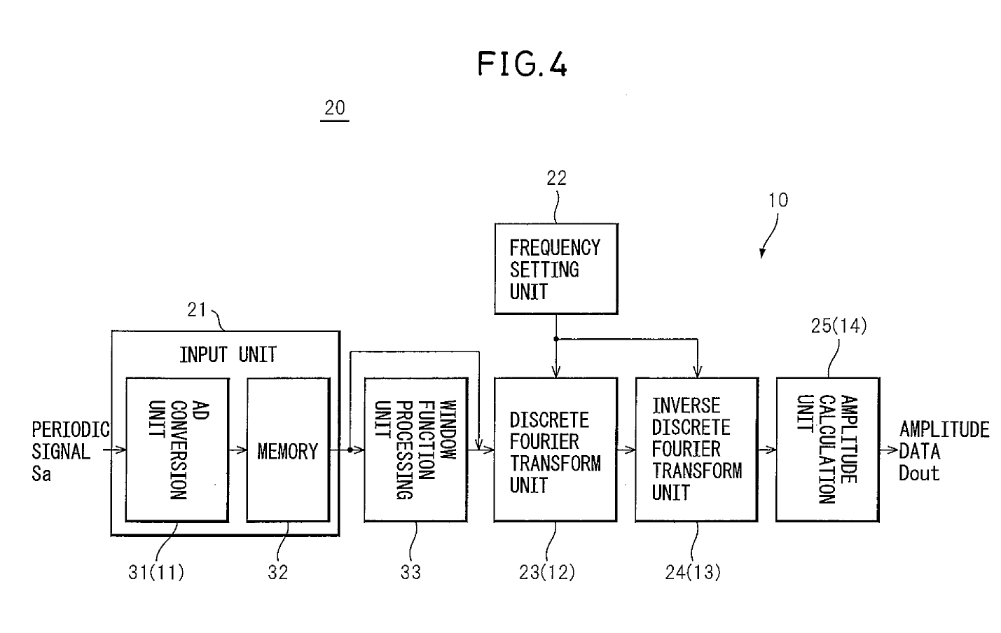

FIG. 4 is a view showing an apparatus for measurement of amplitude according to a second embodiment. This is a more specific aspect of the first embodiment of FIG. 3. In the figure, the apparatus 10 for measurement of amplitude is comprised of the illustrated five functional units 21, 22, 23, 24, and 25, that is, an input unit 21 inputting a periodic signal Sa repeating a certain waveform periodically, a frequency setting unit 22 setting the closest discrete frequencies to the frequencies of fundamental and harmonic frequency components of the periodic signal Sa in a discrete frequency domain, a discrete Fourier transform unit 23 which calculates fundamental and harmonic frequency components corresponding to the thus set discrete frequencies by a discrete Fourier transform, an inverse Fourier transform unit 24 applying an inverse Fourier transform to the values of the frequency components and summing the results to reconstruct the waveform in the time domain, and an amplitude calculation unit 25 calculating the amplitude of the periodic signal Sa based on the waveform data at the center of the waveform on the time axis.

The apparatus preferably is further provided with the following functional units, that is, the input unit 21 includes an AD conversion unit 31 for converting the periodic signal Sa to a digital signal and a memory 32 for holding the output of the AD conversion unit 31.

Further, it may be provided with a window function processing unit 33 multiplying a window function with the signal (Sd) applied from the input unit 21 to the discrete Fourier transform unit 23.

The above-mentioned apparatus for measurement of amplitude of a periodic signal can be applied to for example an apparatus for testing a magnetic head. The test apparatus 20 uses the apparatus 10 for measurement of a periodic signal described in FIG. 3 or FIG. 4 to measure the + side amplitude and − side amplitude of the periodic read back signal from a magnetic head, which is a part of the evaluation of characteristics of magnetic heads.

If comparing the above method of the present invention with the above known example (FIG. 22), the present invention reconstructs the waveform from the fundamental and harmonic frequency components of the periodic signal Sa in a frequency domain in the same way as the known example, but there is only one AD conversion system in the present invention. The periodic signal Sa to be measured is directly converted by AD conversion and the amplitudes of the fundamental and harmonic frequency components are directly measured without using a reference system such as in the known example. Therefore, preferably, by performing a window function processing for high precision amplitude and also using the magnitudes and phases of the fundamental and harmonic frequency components, only at the points in the discrete frequencies closest to the fundamental frequency and the harmonic frequencies, for reconstructing the waveform and simultaneously determining the maximum value and minimum value of the reconstructed waveform at the center part on the time axis as the + amplitude and the − amplitude, whereby it becomes possible to perform high precision measurement and realize a smaller circuit size without being affected by leakage of the frequency component.

Next, the present invention will be explained in detail while referring to waveform diagrams etc.

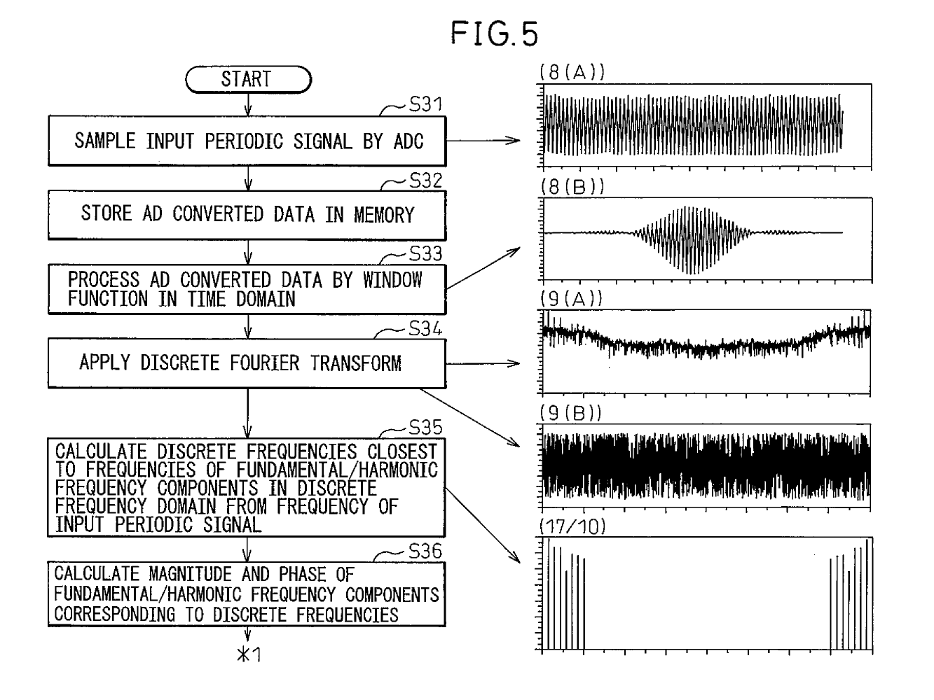

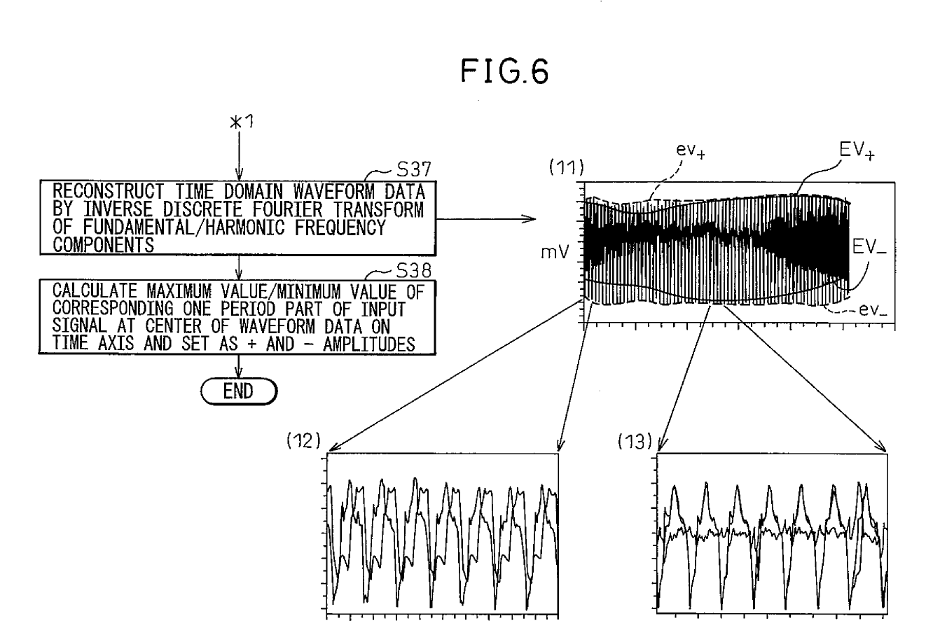

FIG. 5 is a first part of a view showing the flow of processing based on the present invention, while FIG. 6 is a second part. In FIG. 5 and FIG. 6, the following are shown:

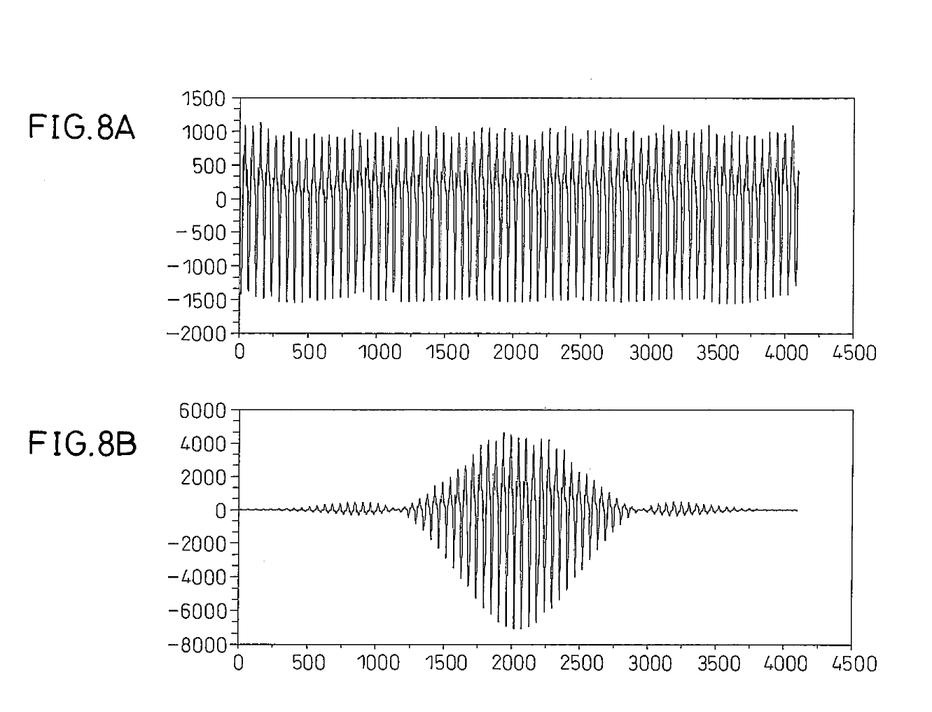

Step S31: the input periodic signal Sa is sampled by the AD conversion unit 11. The sampled waveform is shown in FIG. 8A. Note that 8(A) corresponds to the later explained FIG. 8A (below, the same in FIG. 5 and FIG. 6).

Step S32: The AD converted data is stored in the memory 32.

Step S33: The AD converted data is processed by a window function in a time domain (8(B)).

Step S34: The data processed by the window function is transformed by the discrete Fourier transform unit 12 (9(A), 9(B)).

Step S35: The discrete frequencies closest to the frequencies of the fundamental frequency component and the harmonic frequency components in a discrete frequency domain are calculated from the frequency of the input periodic signal (17/10).

Step S36: The magnitudes and phases of the fundamental frequency component and harmonic frequency components corresponding to the discrete frequencies are calculated. In the present invention, for convenience of explanation, the discrete Fourier transform was applied at step S34 and the data of all discrete frequency points was shown, but in actuality it is sufficient to apply a discrete Fourier transform at step S36 only to the discrete frequency points calculated at step S35.

Step S37: The waveform data in the time domain is reconstructed by applying an inverse discrete Fourier transform to the fundamental frequency component and harmonic frequency components and adding the results (11).

Step S38: The maximum value and minimum value of the center part (11) of the waveform data on a time axis are calculated and determined as the + side amplitude and − side amplitude.

This processing will be explained in more detail while referring to the overall flow of processing of the present invention shown in FIG. 5 and FIG. 6.

As already explained, the present invention can be applied to the general measurement of the + amplitude/− amplitude of a periodic signal, but the explanation will be given taking as an example a reproduced waveform from a magnetic head when repeating magnetic transitions at a certain period.

When the periodic waveform of the period T in a continuous time domain is x(t), the Fourier transform X(f) includes only a 1/T multiple frequency component. However, if applying a discrete Fourier transform by using data of a finite length obtained by sampling the x(t) with a certain sampling frequency Fs, in the general case where this sampling frequency Fs is not a whole multiple of the frequency 1/T of the periodic waveform, the inherent frequency component ends up being separated into a plurality of discrete frequency components, due to a phenomenon called frequency leakage.

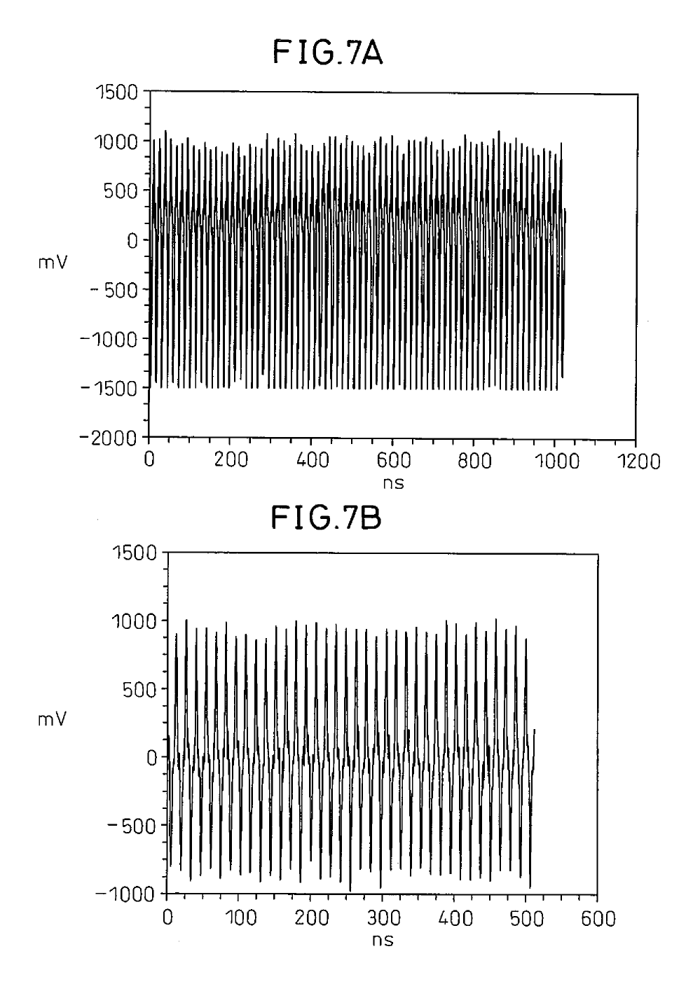

To avoid this phenomenon and precisely calculate the magnitude and phase of the frequency components contained in a signal in a time domain, usually multiplication of the signal in the time domain with a window function before applying a discrete Fourier transform such as a fast Fourier transform (FFT) etc is performed. Here, see FIG. 7.

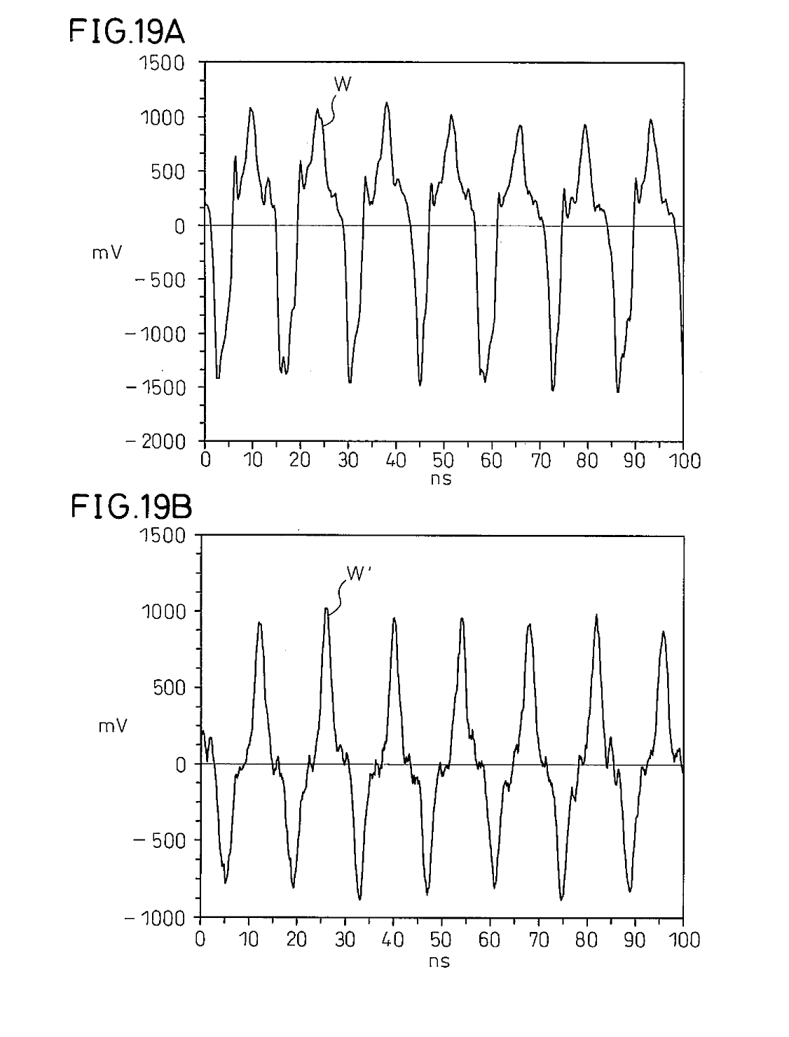

FIG. 7 are view showing examples of waveforms of actual read back signals from magnetic heads, where FIG. 7A shows asymmetry of a waveform and FIG. 7B shows symmetry. The actual magnetic head signals shown in FIG. 7A and FIG. 7B are waveforms of 4096 points obtained by sampling the waveforms partially shown in the above-mentioned FIG. 19A and FIG. 19B at 4 GSPS and 8 GSPS. Window functions are further multiplied with these waveforms.

FIG. 8A is a view showing the same waveform as FIG. 7A, while FIG. 8B is a view showing the waveform obtained by multiplying a window function with the waveform of FIG. 8A. (Note that for simplification, the explanation of FIG. 7B will be omitted, but the explanation is exactly the same as the case of FIG. 7A.) As the window function in this case, a Flat Top Window was used and multiplication was performed in a time domain. Further, a discrete Fourier transform is applied to the waveform after the above multiplication.

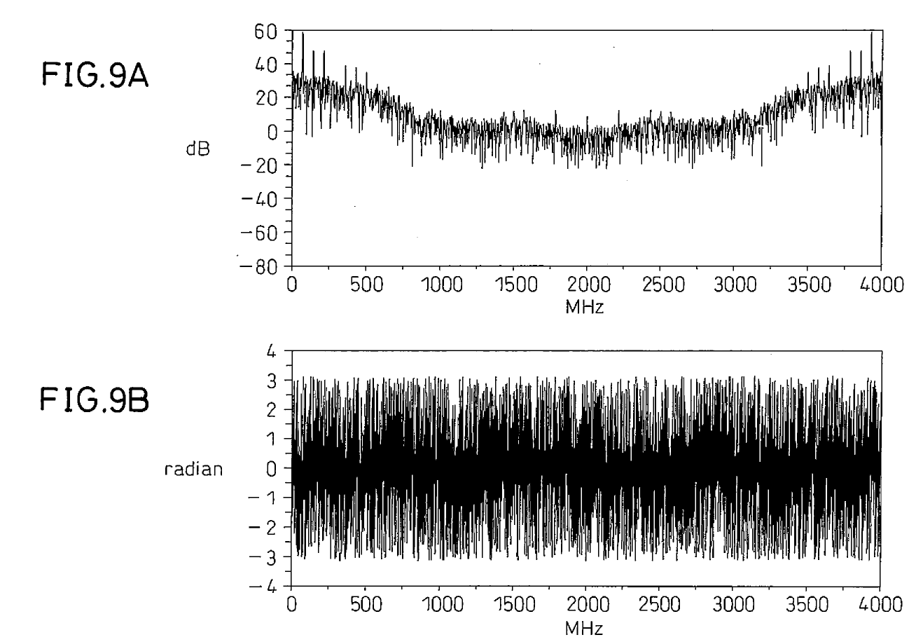

FIG. 9 are views showing the amplitude (FIG. 9A) and phase (FIG. 9B) of the results of application of a discrete Fourier transform to the waveform of FIG. 8B. That is, they show the frequency (MHz) characteristics of the amplitude (dB) and phase (radians) resulting from application of the discrete Fourier transform, for example, an FFT, to a waveform processed with a window function of a Flat Top Window of FIG. 8B. The results of the FFT shown in FIGS. 9A and 9B include many sprious components, other than the fundamental and harmonic frequency components, due to noise etc. in addition to the leakage of the frequency component. In this case, if the waveform to be measured is a waveform having a period T strictly, frequency components other than the fundamental and harmonic frequency components would not be included. For this reason, the components, after removal of the above sprious components, can be deemed as a waveform purely reproduced by the magnetic head, that is, by the magnetic head itself.

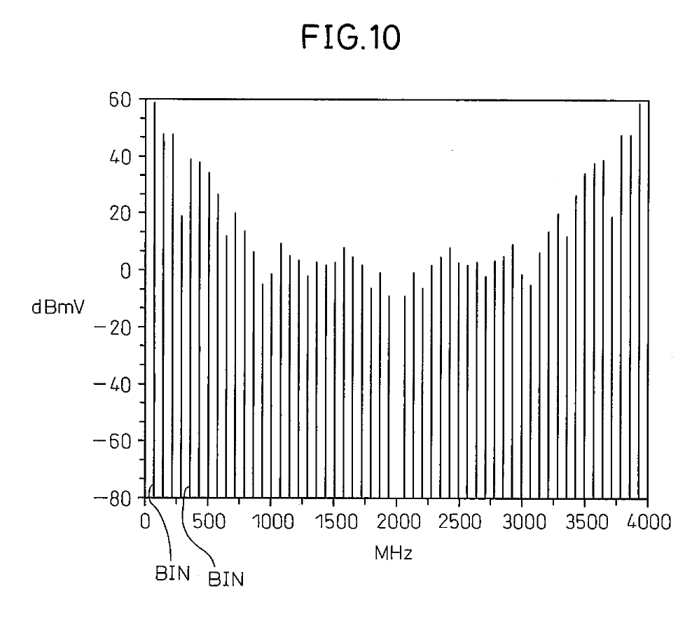

Therefore, by choosing only the FFT frequency components corresponding to the fundamental frequency and harmonics of the magnetic transition frequency of the magnetic head, while setting the other frequency components as 0, and then applying a discrete Fourier transform, for example, an inverse fast Fourier transform (IFFT), it becomes possible to obtain a waveform of a time domain reproduced from the magnetic head itself. The reproduced waveform based on this measure is shown in FIG. 10.

FIG. 10 is a view showing only the FFT frequency components corresponding to the fundamental frequency and the harmonics. This shows the frequency amplitude characteristics when choosing only the data of the amplitudes and phases corresponding to the fundamental/harmonic components of the FFT shown in FIGS. 9A and 9B and making the other components 0, based on the above measure. However, the BIN frequency of an FFT and magnetic transition frequency are not multiples of each other in relation, so data of only single BINs corresponding to the fundamental frequency and harmonics closest to multiples of the magnetic transition frequency are chosen. These data are transformed back to data in a time domain.

FIG. 11 is a view showing the waveform after transforming the waveform in the frequency domain of FIG. 10 back to the time domain. That is, if transforming the waveform data in the frequency domain of FIG. 10 to waveform data in the time domain by IFFT, waveform data surrounded by the envelopes EV+ and EV− of FIG. 11 are obtained. On the other hand, the waveform data surrounded by the envelopes ev+ and ev− in FIG. 11 are read back signal waveforms from the actual magnetic heads shown in FIG. 7A and FIG. 8A.

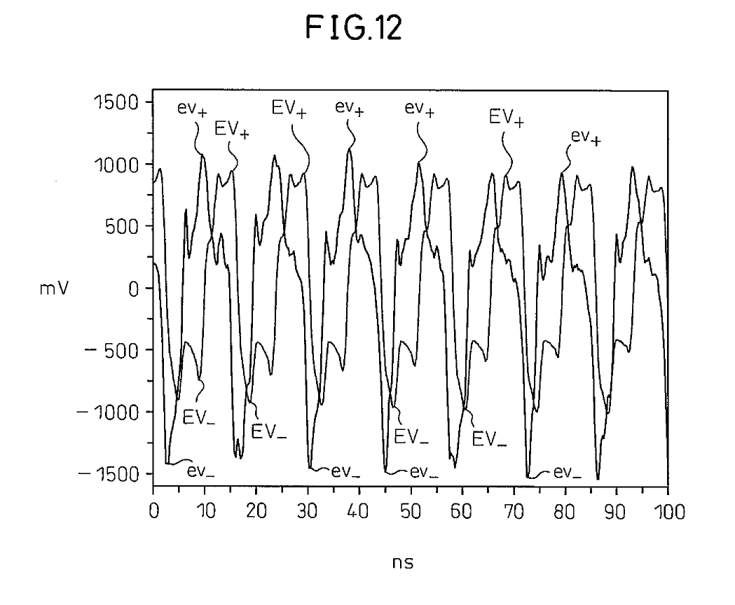

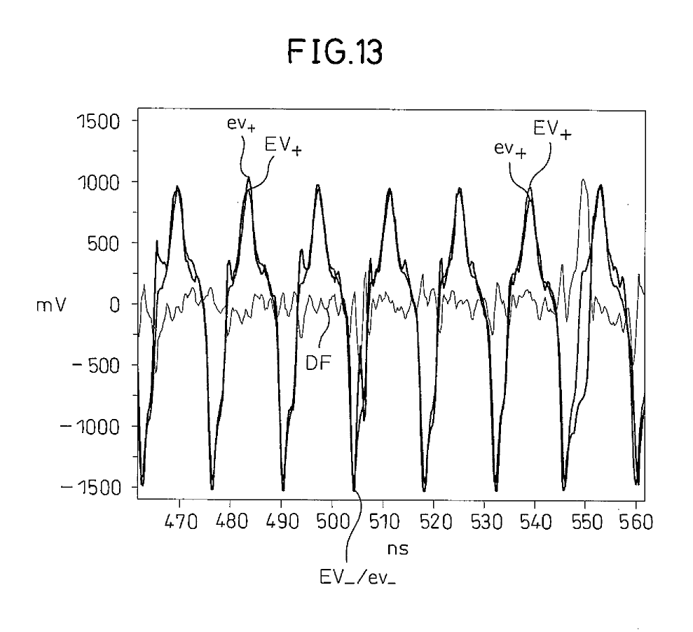

When viewing FIG. 11 in more detail, at the “head part” and “tail part” of the figure, the waveform EV+-EV− reconstructed in the time domain has a large deviation from the original waveform ev+-ev− (FIG. 12). However, at this “center part”, the deviation between the waveform EV+-EV− and the original waveform ev+-ev− is small (FIG. 13). Thus, a precisely matched waveform is obtained.

FIG. 12 is an enlarged view of part of the head part of FIG. 11, while FIG. 13 is an enlarged view of part of the center part of FIG. 11. By inversely converting the data of the frequency domain corresponding to the fundamental frequency component and the harmonic frequency components to data of the time domain with an inverse discrete Fourier transform (IDFT) and summing the data of these frequency components, it becomes possible to precisely reproduce the original waveform at the center part, on the time axis, of the waveform data after reconstruction. Note that the line DF at the center in FIG. 13 shows the difference between the reconstructed waveform (EV+-EV−) and the original waveform (ev+-ev−). This shows that the difference is substantially 0.

Therefore, by searching the maximum value and minimum value of the data in a time range corresponding to the magnetic transition period at the center part of the waveform data in the time domain reconstructed in that way, it becomes possible to measure the average + amplitude and − amplitude of the original waveform. Note that the symmetry/asymmetry of the amplitude of the read back signal output from a magnetic head is calculated, in accordance with a certain definition, from the values of the + amplitude and − amplitude found in the above way.

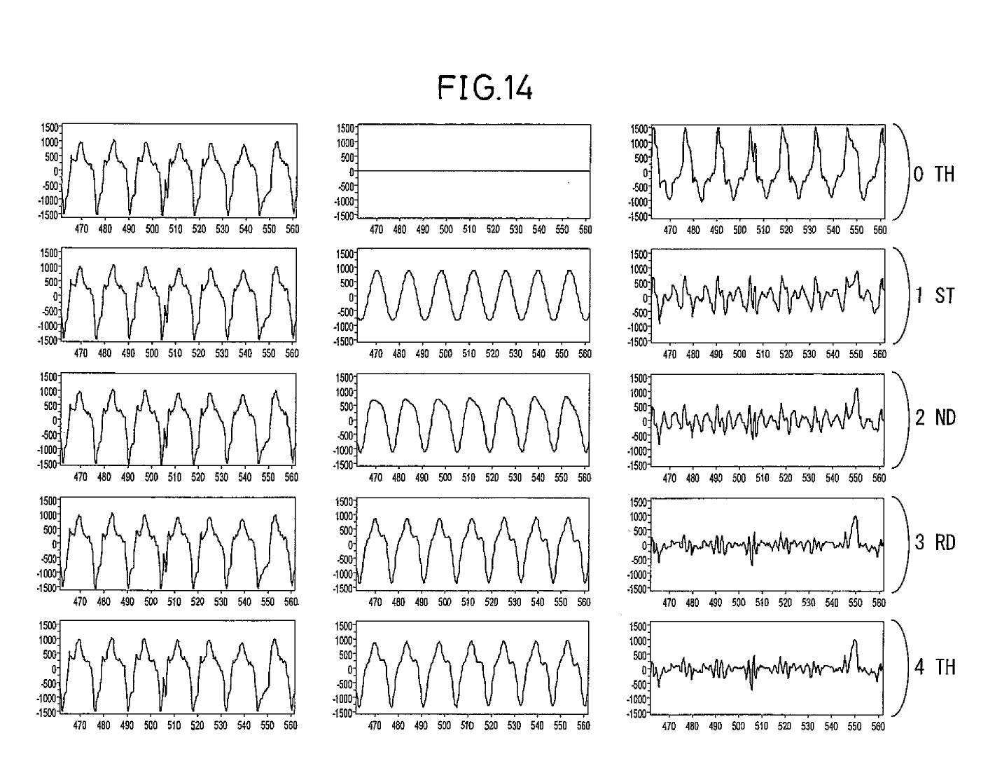

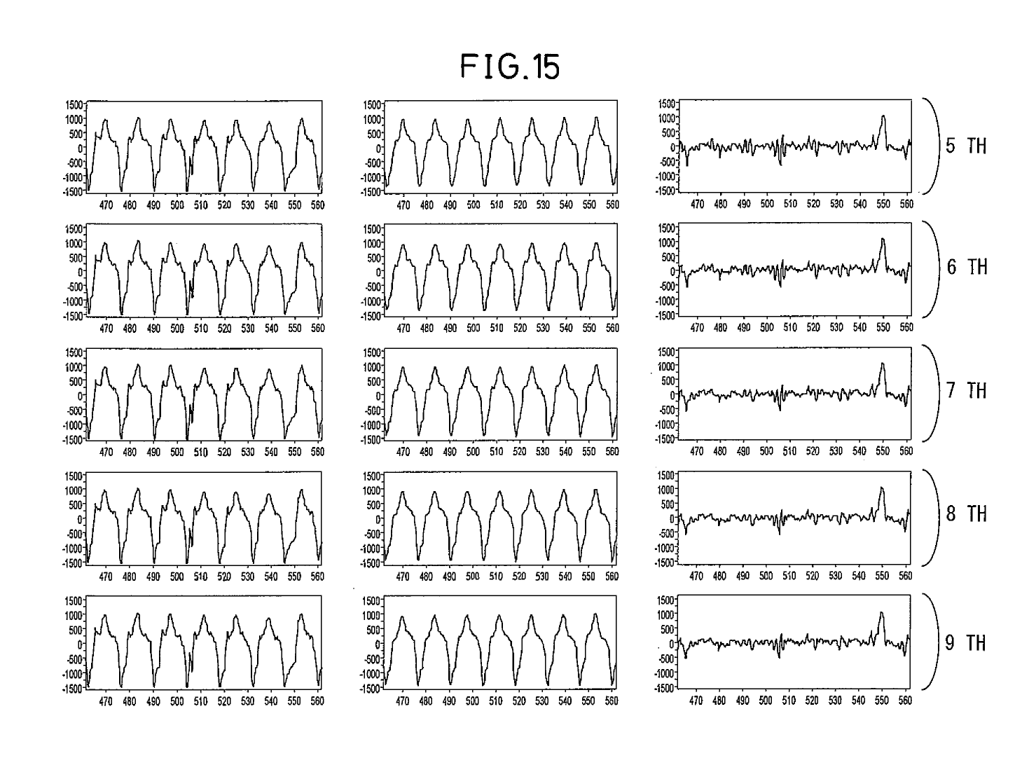

In the above explanation, all of the higher order harmonic components of ½ or less of the sampling frequency are considered and summed to reconstruct the waveform, but the higher the order, the smaller the amplitude of the harmonic components and the smaller the effect on the reconstructed waveform. This situation is shown in FIG. 14 and FIG. 15.

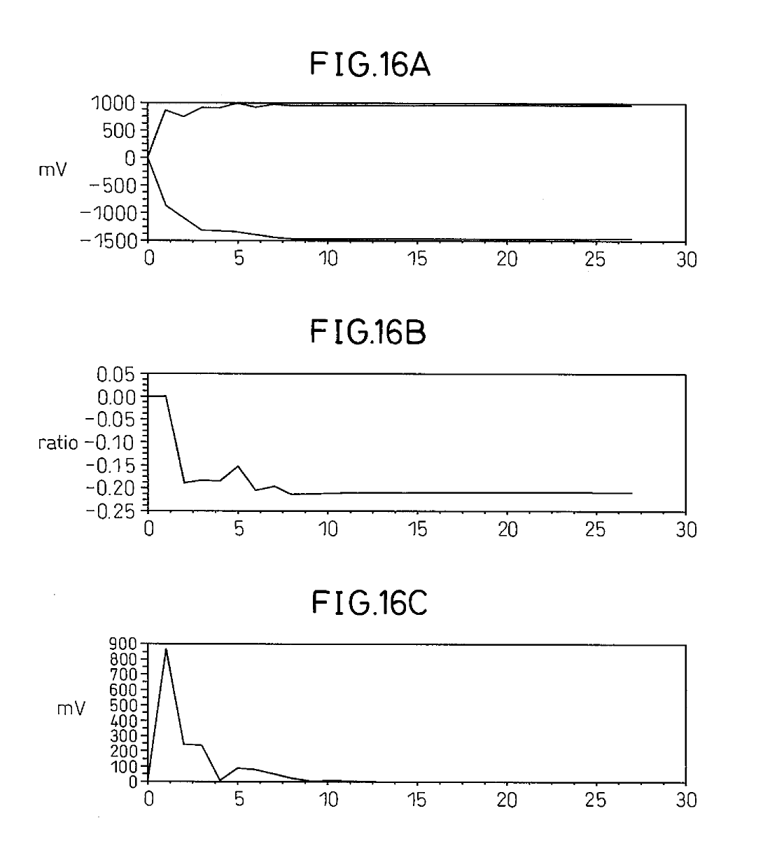

FIG. 14 is a first part showing the relationship between the orders of harmonics and a reconstructed waveform, and FIG. 15 is a second part. In FIG. 14 and FIG. 15, the left column shows the original waveform, the middle column shows the reconstructed waveform of FIG. 13 (EV+-EV−), and the right column shows the difference between the waveform of the right column and the waveform of the middle column. On the other hand, the topmost parts of the middle column and right column show the waveform of the 0th wave component (DC component), the second part (next row) shows the summed waveform up to the first order (fundamental frequency component), the third part (row) shows the summed waveform up to the second order, . . . the bottommost part (row) shows the added waveform up to the ninth order. Further, FIG. 16 show that the higher the order, the closer to the saturation level, wherein FIG. 16A shows the + amplitude side, FIG. 16C the − amplitude side, and FIG. 16B the ratio of these two, where this ratio is expressed by (A₊−A₋)/(A₊+A₋). The amplitude is indicated by mV. The abscissa shows the order.

Ultimately, it is learned that, in the case of the waveform of this example, it is sufficient to consider up to around the seventh order as harmonic components. Therefore, the discrete Fourier transform to calculate the frequency components and the inverse discrete Fourier transform to inversely calculate the waveform of the time domain are not necessary to be executed on all frequency points of FFT, but it is sufficient to apply a discrete Fourier transform and inverse discrete Fourier transform to only points corresponding to the predetermined frequency points of the fundamental frequency component and harmonic frequency components.

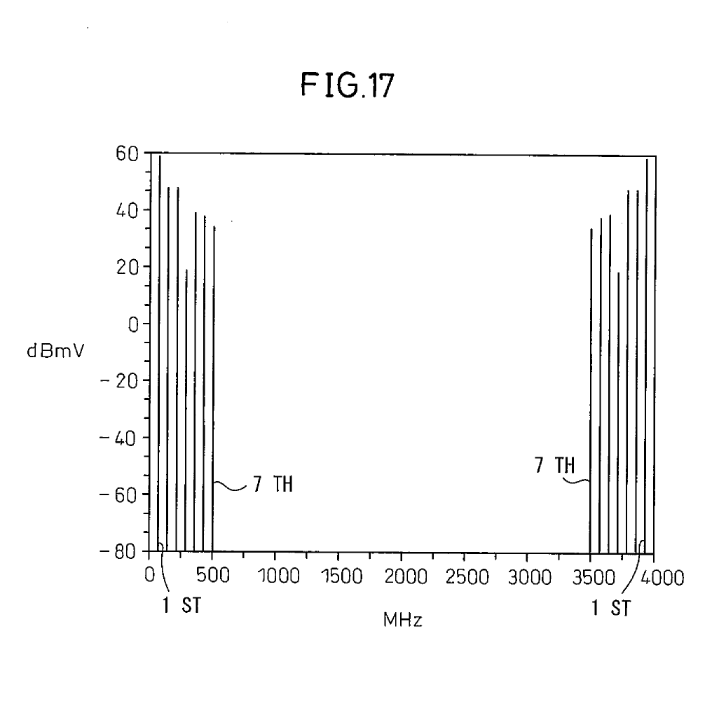

FIG. 17 is a view showing a waveform when reconstructing a waveform when using harmonic frequency components up to seventh order.

The above explanation was given taking as an example the waveform of a read back signal from a magnetic head, but can also be applied to general measurement of the + side amplitude and − side amplitude of a periodic signal. By determining the order of the harmonics to be used, in accordance with the desired precision, reconstructing the waveform by fundamental and harmonic components up to the above determined order, and searching the maximum value and minimum value of the waveform data at the center part of the reconstructed waveform on a time axis, it is possible to precisely calculate both the average + side amplitude and average − side amplitude of the periodic signal being measured.

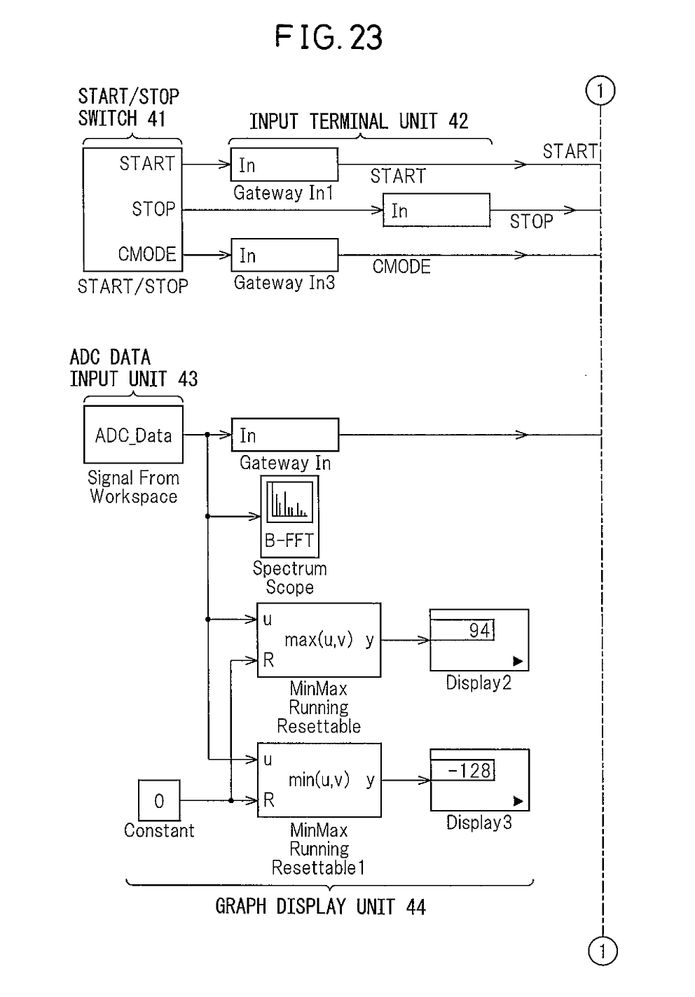

Further, the method of measurement of amplitude explained above can be realized by software or can be realized completely by hardware. Finally, as reference, examples of realization by actual design, completely by hardware, are shown in FIG. 23 to FIG. 45. However, only the arrangement of the various functional blocks will be shown. The detailed explanation of the operation will be omitted.

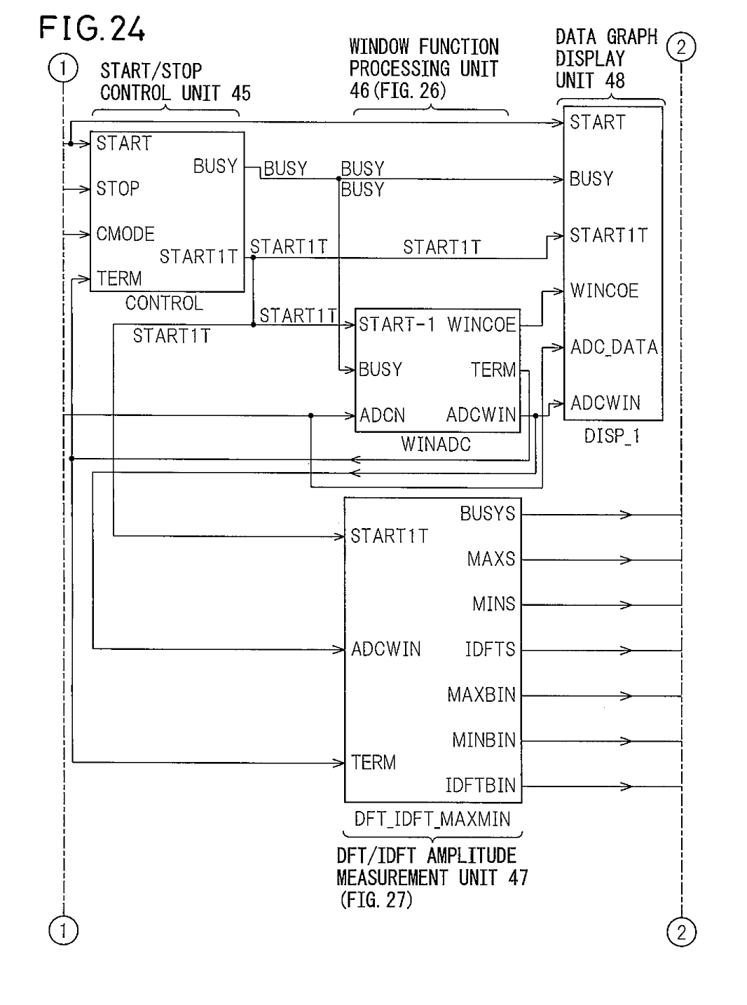

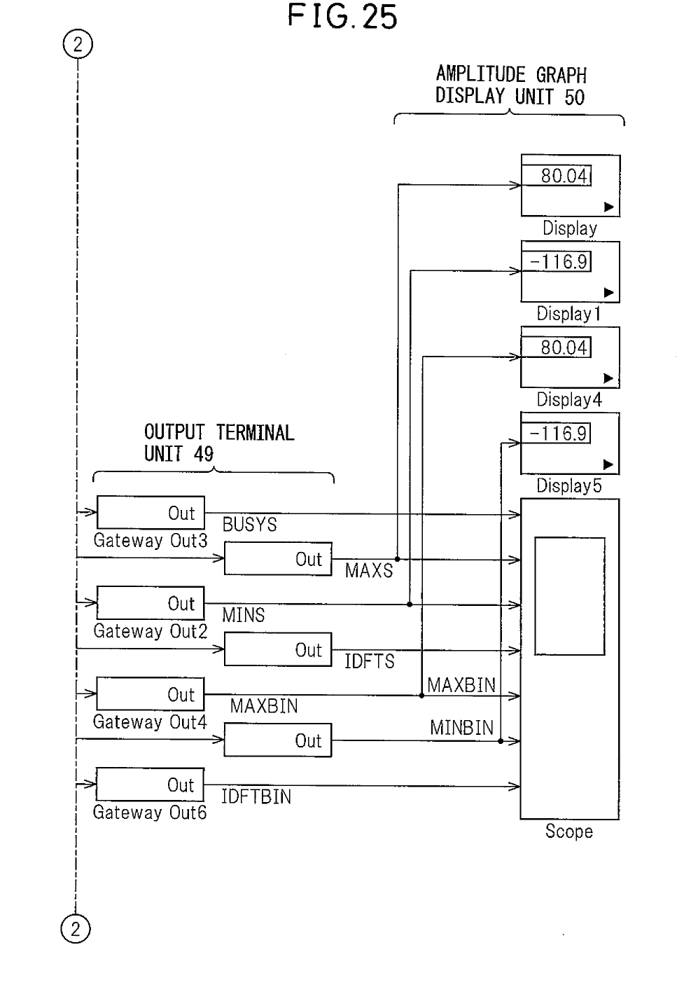

FIG. 23 is a first part of a view of the overall configuration of an apparatus for measurement of amplitude using a DFT/IDFT, FIG. 24 is a second part and FIG. 25 is a third part thereof.

The bottom part of FIG. 23 shows an ADC input unit 43 inputting ADC data from the above-mentioned AD conversion unit (ADC). Note that a graph display unit 44 only monitors the ADC data.

On the other hand, the top part of FIG. 23 shows an input terminal unit 42 of a circuit part of FIG. 24 and a start/stop switch 41 of the stage before. This start/stop switch 41 controls the starting and stopping of measurement.

FIG. 24 shows the above-mentioned window function processing unit 46 and a DFT/IDFT amplitude measurement unit 47 corresponding to the above-mentioned discrete Fourier transform unit (DFT) and inverse discrete Fourier transform unit (IDFT). Before these, a start/stop control unit 45 is provided. After it, a data graph display unit 48 is provided. Note that the figure numbers in parentheses show numbers of later explained figures expanded to detailed parts.

FIG. 25 shows an output terminal unit 49 of output data showing amplitude from the DFT/IDFT amplitude measurement unit 47 and an amplitude graph display unit 50 displaying these amplitude output data by a graph.

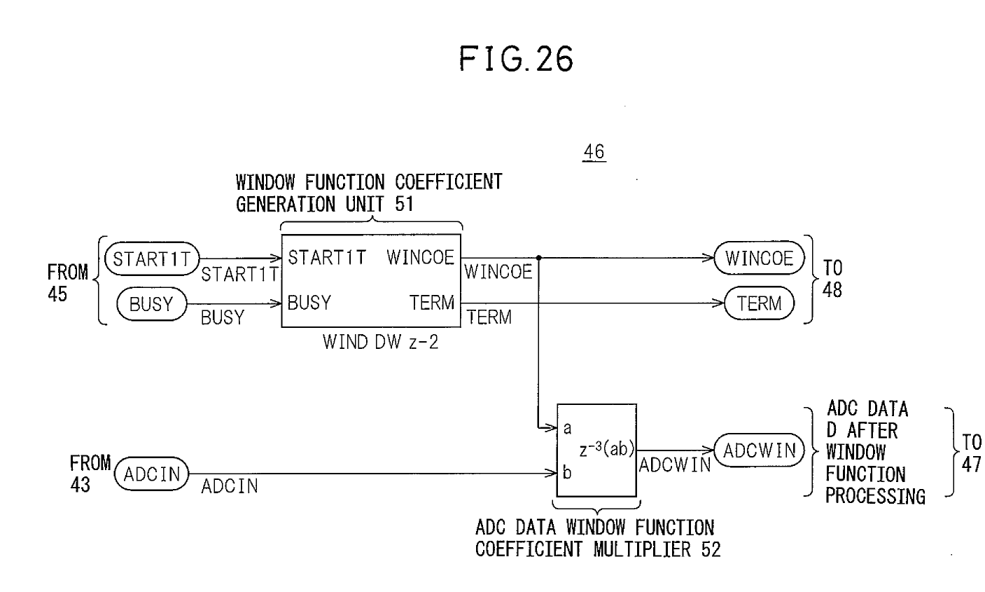

FIG. 26 is a view showing details of the window function processing unit 46 of FIG. 24. The processing unit 46 is comprised of a window function generation unit 51 and a multiplier 52 of the ADC data and window function coefficients. Note that the Z⁻³ in the figure shows a delay element which delays the input signal by 3 clocks. The output of this multiplier 52, that is, the ADC data D after the window function processing (above FIG. 8B), is input to the DFT/IDFT amplitude measurement unit 47 of FIG. 24.

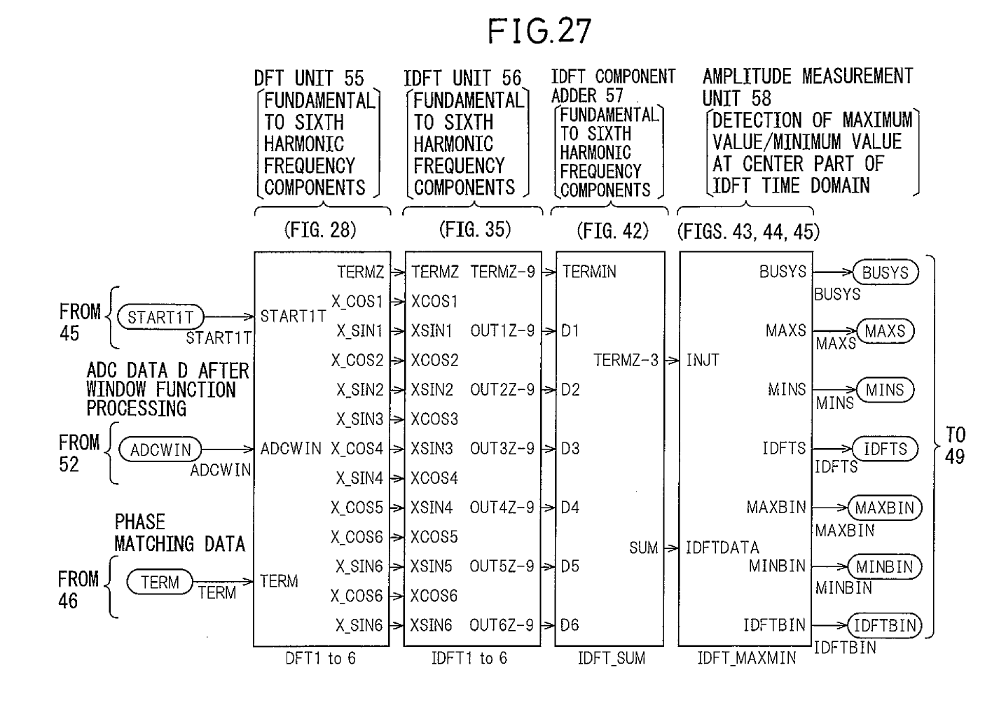

FIG. 27 is a view showing details of the DFT/IDFT amplitude measurement unit 47 of FIG. 24. Here, a DFT unit 55, an IDFT unit 56, an IDFT component adder 57, and an amplitude measurement unit 58 generating the target amplitude measurement data are shown. Note that here the fundamental frequency component and harmonic frequency components up to sixth order are processed.

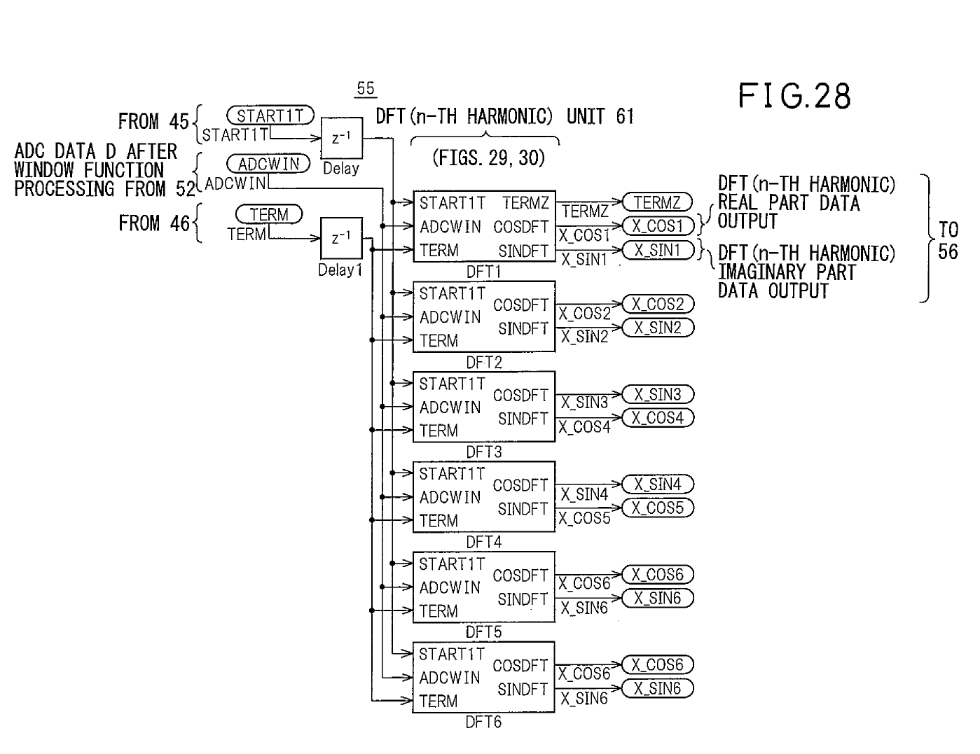

FIG. 28 is a view showing details of the DFT unit 55 of FIG. 27. The main part of this figure shows the DFT (n-th harmonic) units 61 corresponding to the first harmonic to sixth harmonic (n−1, 2 . . . 6). Note that Z⁻¹ is a one clock worth delay element.

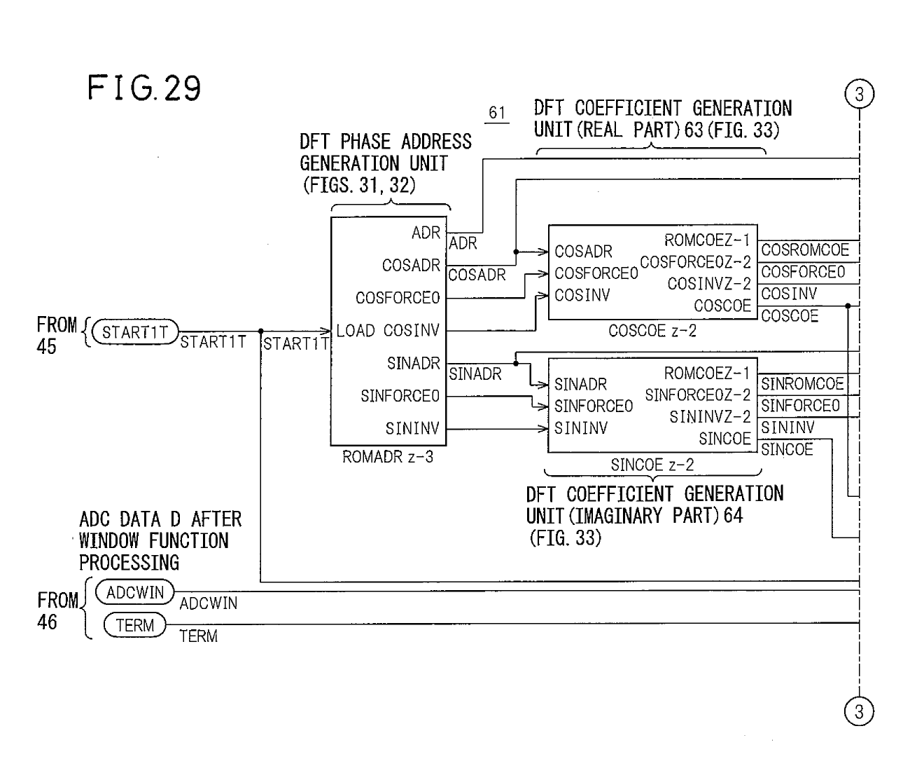

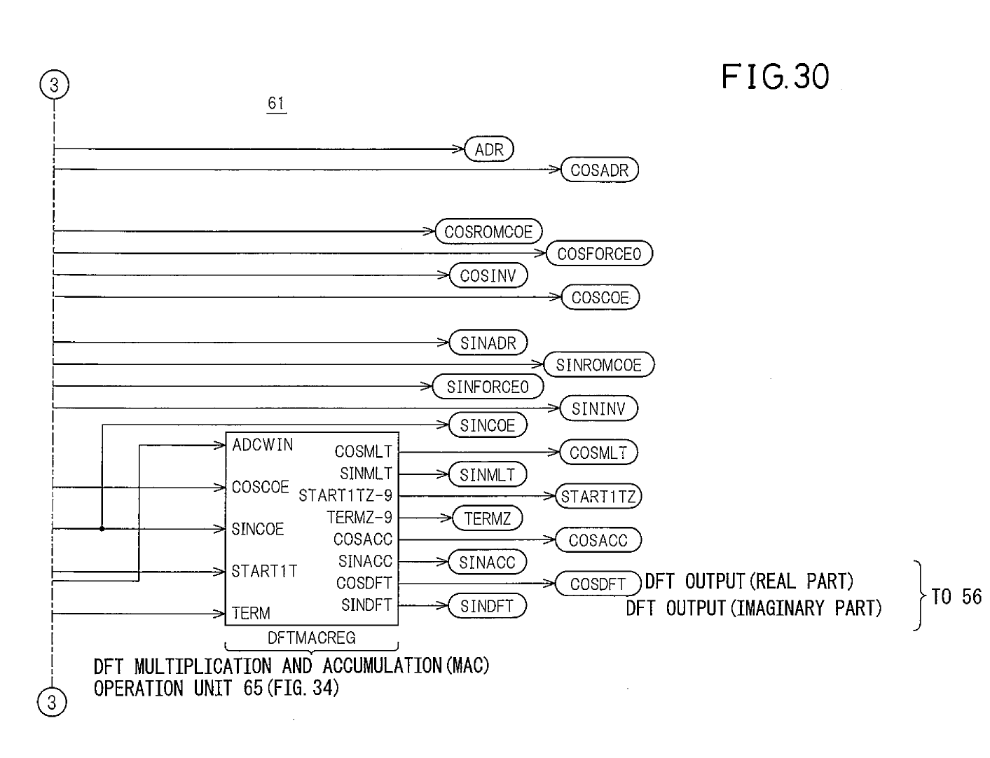

FIG. 29 is a first part of a view showing details of a DFT (n-th harmonic) unit 61 of FIG. 28, while FIG. 30 is a second part. Note that the DFT unit 61 of FIG. 28 is comprised of six blocks corresponding to the first, second . . . sixth harmonics (n=6). Therefore, FIG. 29 and FIG. 30 show any one of the above six blocks.

In FIG. 29, a DFT phase address generation unit 62, a DFT coefficient generation unit (real part) 63, and a DFT coefficient generation unit (imaginary part) 64 are shown. Further, FIG. 30 shows a DFT multiplication and accumulation (MAC) operation unit 65.

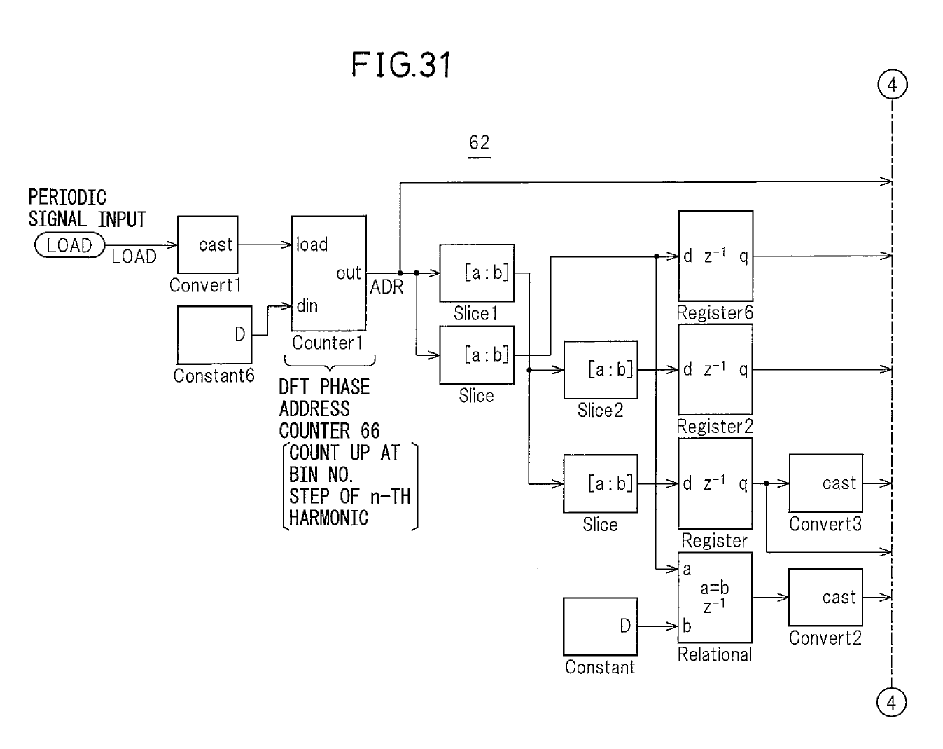

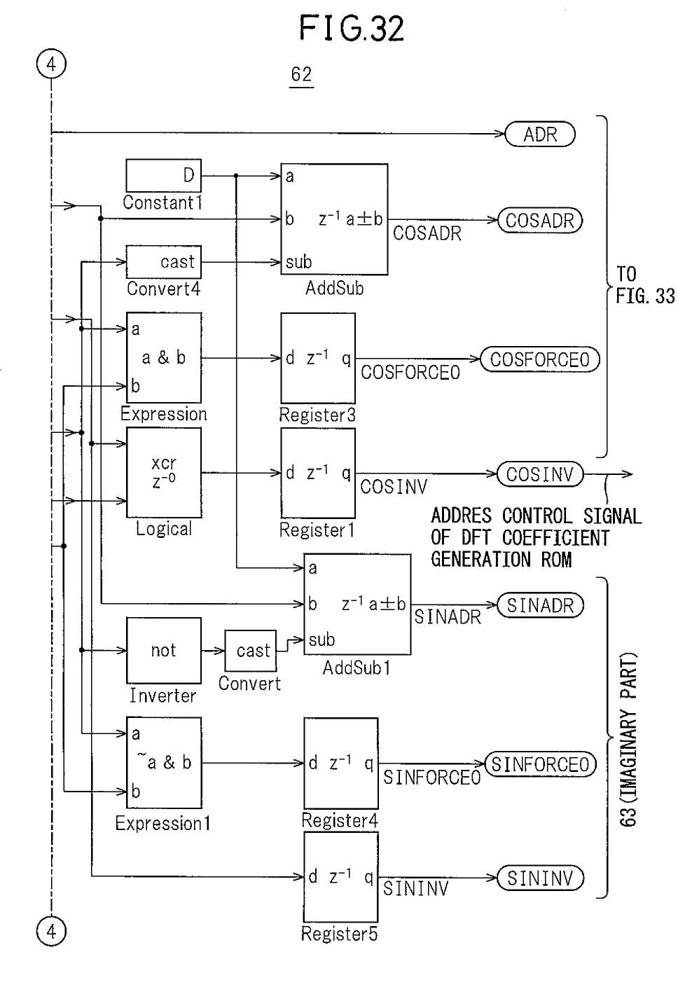

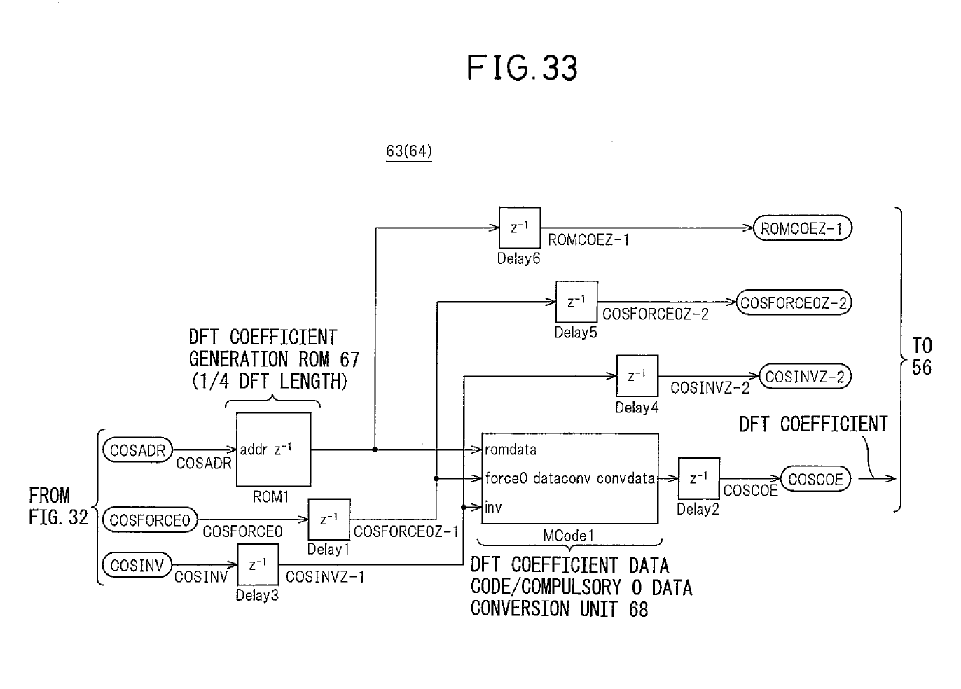

FIG. 31 is a first part of a view showing details of the DFT phase address generation unit 62 of FIG. 29, while FIG. 32 is a second part. FIG. 31 shows a DFT phase address counter 66. This counter 66 is the part generating information on which phase of the frequency component to be measured the phase is. In the end, this generates the address of the DFT coefficient generating ROM 67 shown in FIG. 33 or generates a control signal. This ROM 67 has a table of the coefficients of the cos component and sin component when applying a DFT. However, there is no need to hold all of the coefficients. If taking note of the correlation between the cos and sin between the 0 to 2π phases and the similarity between the ¼ quadrant to 4/4 quadrants, it is for example possible to simply calculate the data of the 2/4 to 4/4 quadrants and possible to simply calculate the data relating to the sin by only the data of the ¼ quadrant relating to the cos. This becomes a major reduction in the required size of the ROM 67. The above control signal is a signal contributing to this reduction.

FIG. 33 is a view showing details of the DFT coefficient generation unit 63 (and 64) of FIG. 29. Note that the real part 63 and imaginary part 64 are both configured the same, so only the real part (63) side is shown. The DFT coefficient generating ROM 67 explained above is shown in FIG. 33. Part of the output of the ROM 67 is input through the DFT coefficient data code conversion and compulsory 0 data conversion unit 68 to the IDFT unit 56. The conversion unit 68 regenerates the original coefficient data from the data of the above reduced sized ROM.

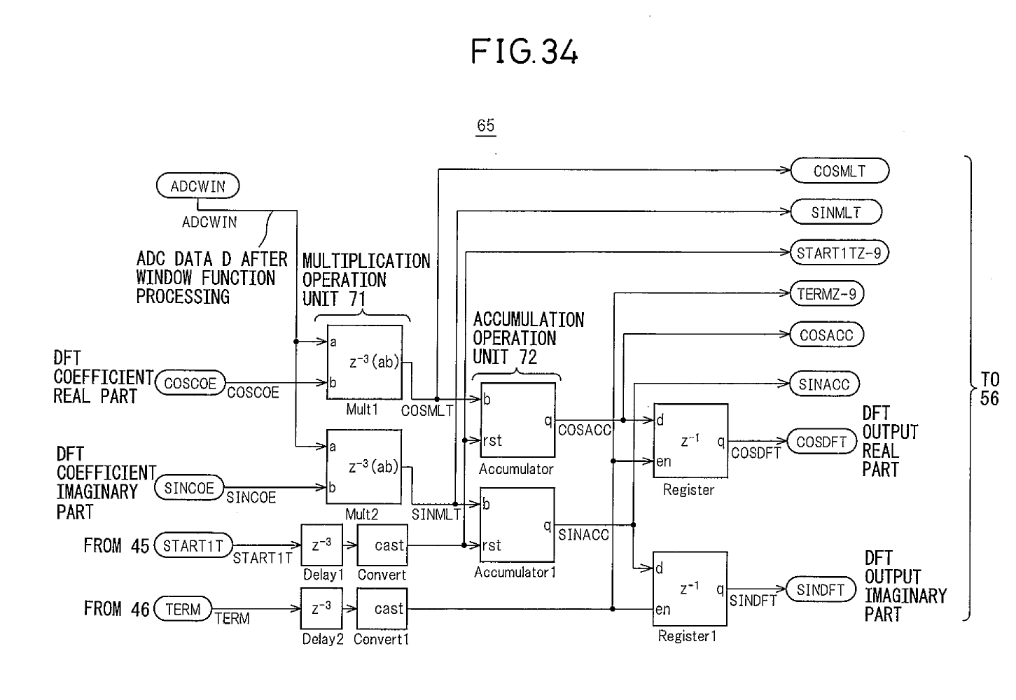

FIG. 34 is a view showing details of a DFT multiplication and accumulation (MAC) operation unit 65 of FIG. 30. It receives as input the ADC data D after window function processing and a DFT coefficient (real part and imaginary part) and obtains a DFT output (real part and imaginary part) through a multiplication operation unit 71 and accumulation operation unit 72 etc.

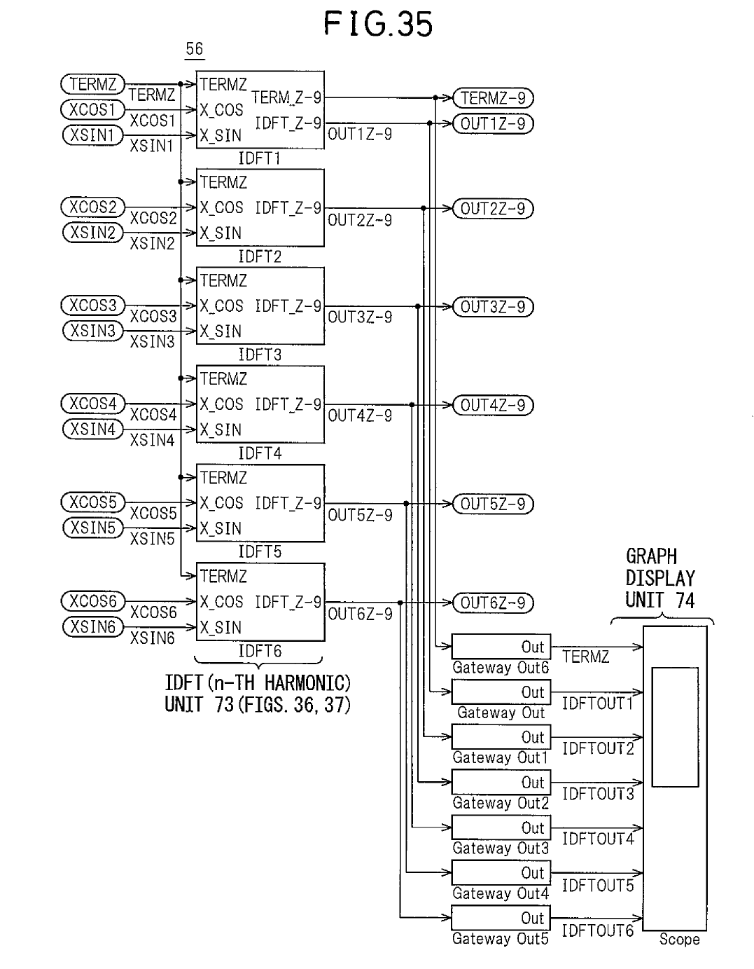

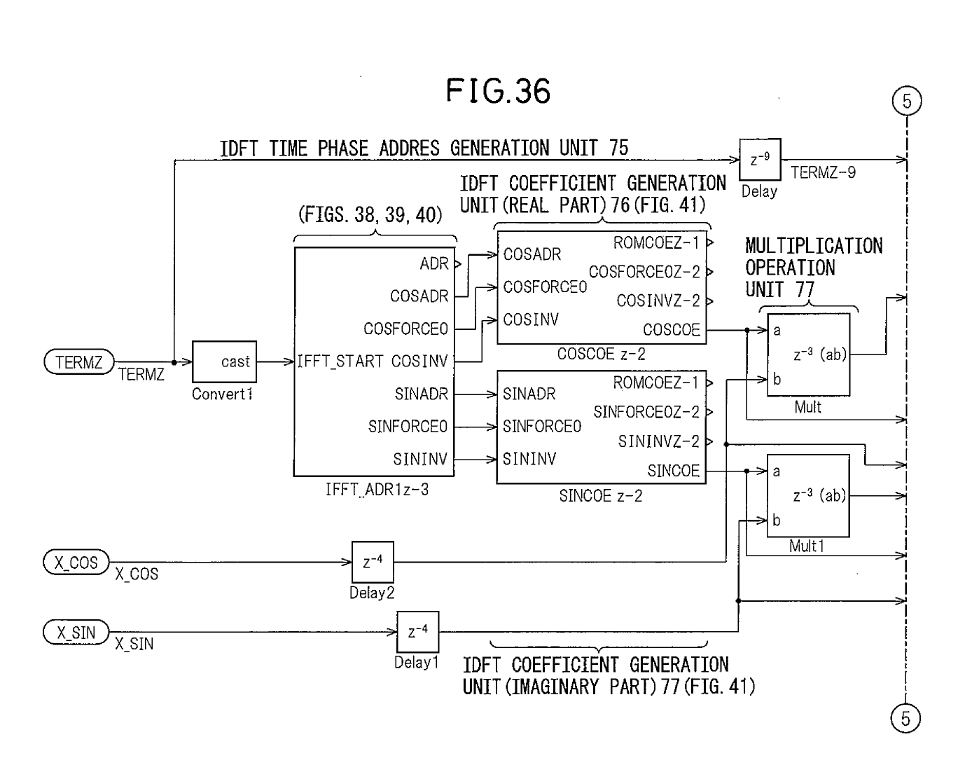

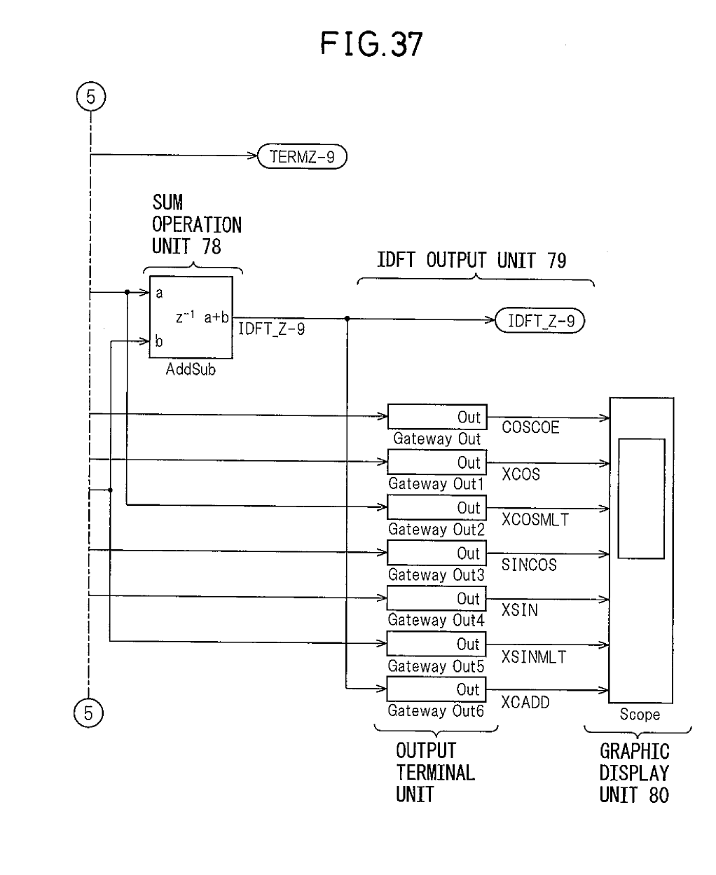

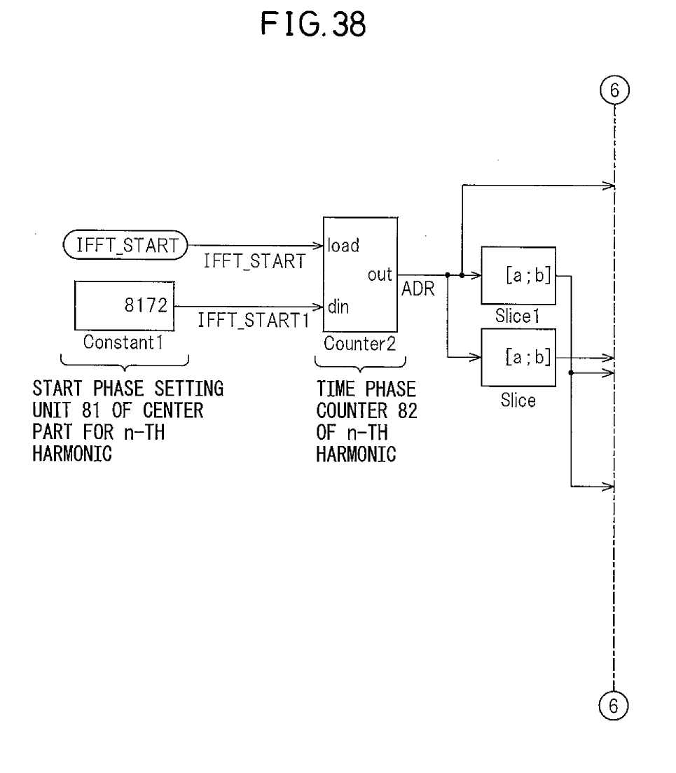

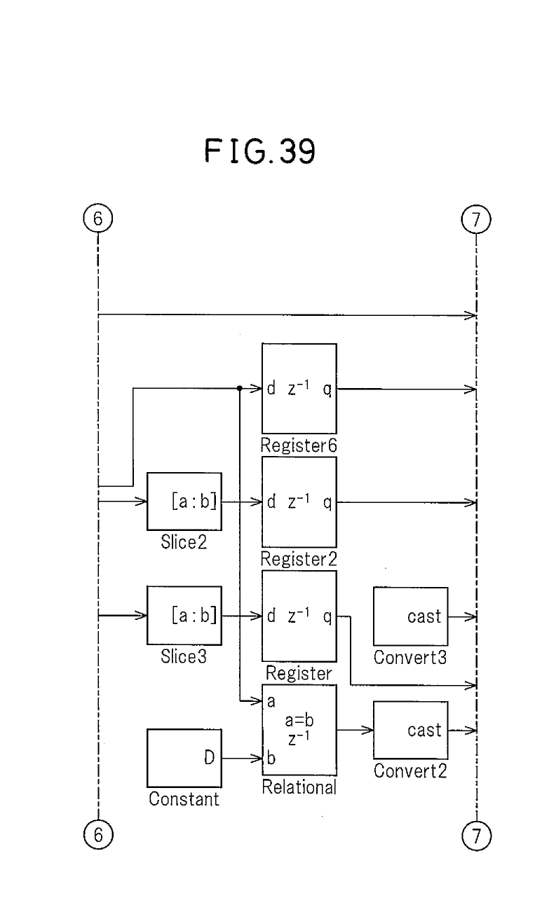

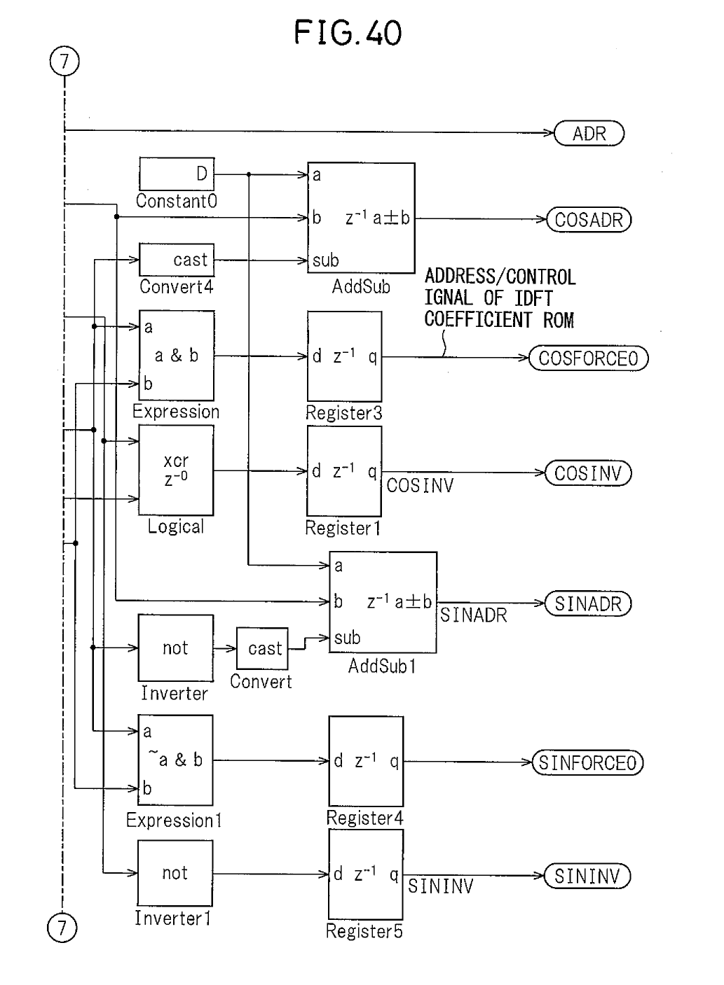

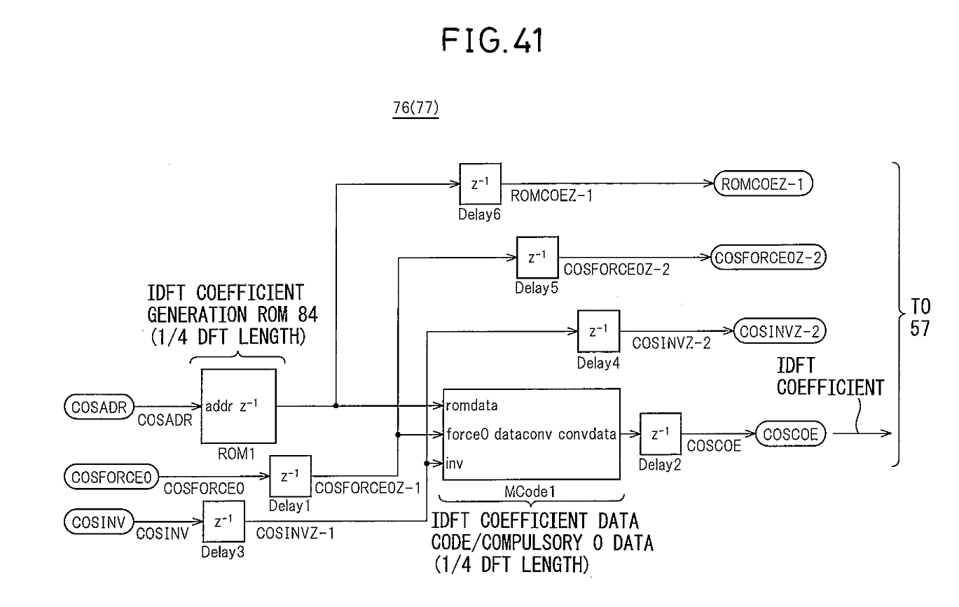

FIG. 35 is a view showing details of an IDFT unit 56 of FIG. 27, FIG. 36 is a first part of a view showing details of an IDFT (n-th harmonic) unit 73 of FIG. 35, FIG. 37 is a second part, FIG. 38 is a first part of a view showing details of an IDFT time phase address generation unit 75 of FIG. 36, FIG. 39 is a second part, FIG. 40 is a third part, and FIG. 41 is a view showing details of an IDFT coefficient generation unit 76 (and 77) of FIG. 36.

Note that the explanation of FIG. 35 to FIG. 41 for the IDFT unit 56 corresponds to the explanation of FIG. 28 to FIG. 34 for the already explained DFT unit 55, that is, FIG. 35 corresponds to FIG. 28, FIGS. 36 and 37 correspond to FIGS. 29 and 30, FIGS. 38, 39, and 40 correspond to FIGS. 31 and 32, and FIG. 41 corresponds to FIG. 33.

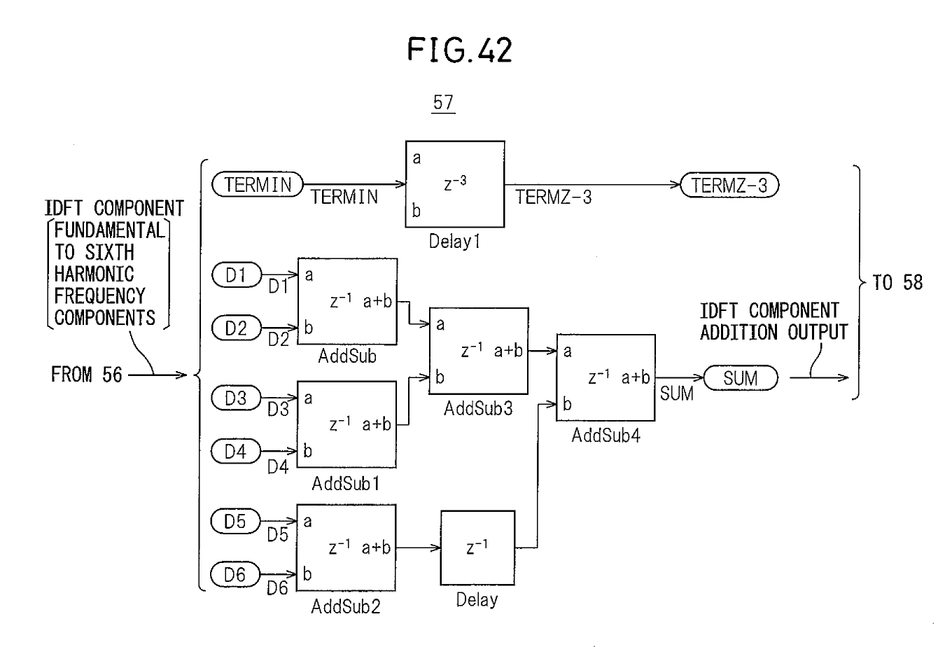

FIG. 42 is a view showing details of an IDFT component adder 57 of FIG. 27. In this figure, five adders (Add Sub) are included.

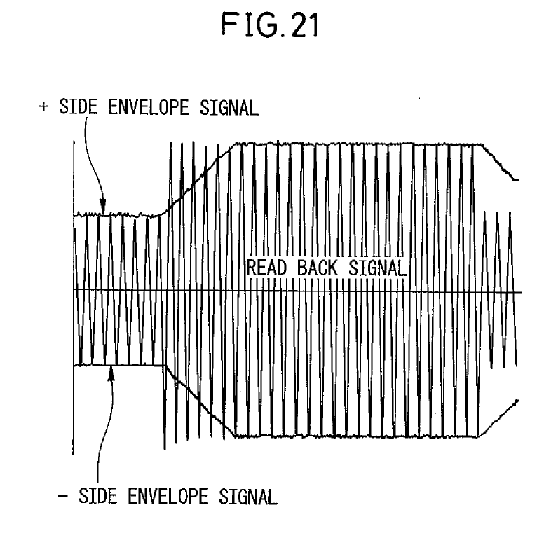

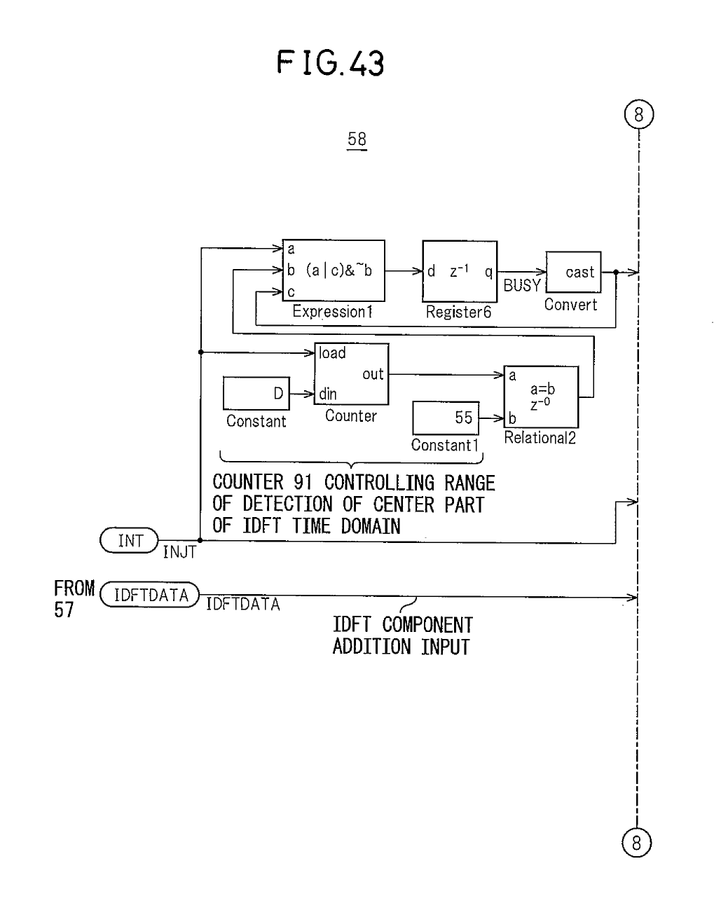

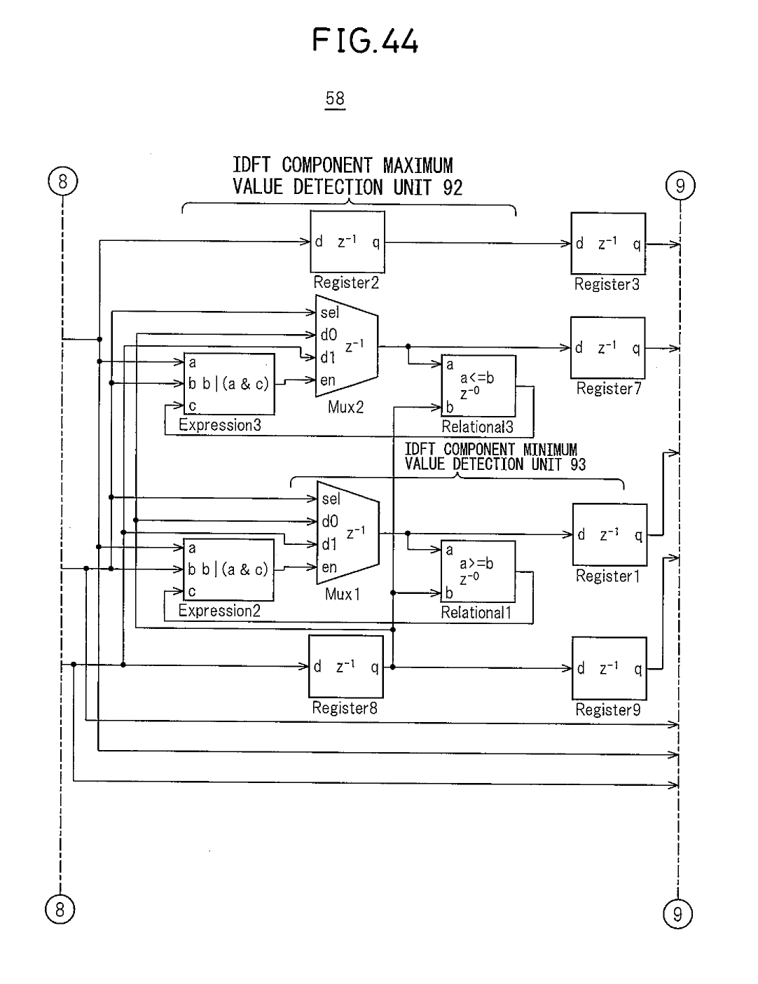

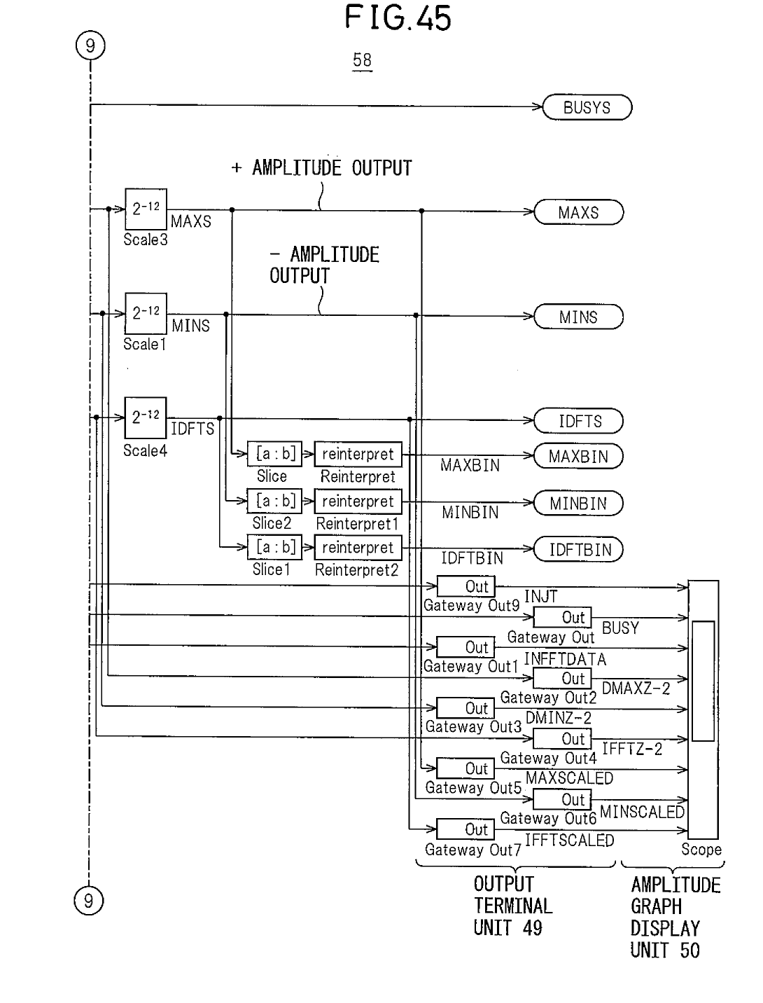

FIG. 43 is a first part of a view showing details of an amplitude measurement unit 58 of FIG. 27, FIG. 44 is a second part, and FIG. 45 is a third part. FIG. 43 shows a counter 91 setting the “center part” of FIG. 11, FIG. 44 shows the maximum value detection unit 92 and minimum value detection unit 93 of the IDFT component. The targeted output data of the + side amplitude and output data of the − side amplitude are obtained. A waveform such as shown in FIG. 21 is observed at the amplitude graph display unit 50 of FIG. 25.

While the invention has been described with reference to specific embodiments chosen for purpose of illustration, it should be apparent that numerous modifications could be made thereto by those skilled in the art without departing from the basic concept and scope of the invention.

1. A method of measurement of a periodic signal including
a step of converting a periodic signal repeating a certain waveform periodically to a digital signal,
a step of applying a discrete Fourier transform to the digital periodic signal and calculating the magnitudes and phases of a fundamental frequency component and harmonic frequency components of the periodic signal in the frequency domain,
a step of applying at inverse discrete Fourier transform to the value of the frequency components and summing the results to reconstruct the waveform in the time domain, and
a step of measuring the amplitude of the periodic signal from the waveform data at the center part of the reconstructed waveform on the time axis.

2. A method of measurement of a periodic signal including
a step of inputting a periodic signal to be measured repeating a certain waveform periodically,
a step of setting the closest discrete frequencies to the frequencies of the fundamental frequency component and harmonic frequency components of the periodic signal in the discrete frequency domain,
a step of applying a discrete Fourier transform to the fundamental frequency component and harmonic frequency components corresponding to the set discrete frequencies to calculate the frequency components,
a step of applying an inverse discrete Fourier to the values of the frequency components of the calculated fundamental frequency component and harmonic frequency components and summing the results to reconstruct the waveform in the time domain, and
a step of calculating the maximum value and minimum value of the waveform based on the waveform data at the center of the reconstructed waveform in the time domain and outputting the + side amplitude and − side amplitude of the periodic signal to be measured from the resultant calculated values.

3. A method of measurement of a periodic signal as set forth in claim 2, wherein
said step of calculating the amplitudes includes a step of calculating phases of said fundamental frequency component and harmonic frequency components in addition to the amplitudes, and
said step of reconstructing the waveform applies an inverse discrete Fourier transform to the values of said amplitudes and the values of said phases and sums respective values.

4. A method of measurement of a periodic signal as set forth in claim 2, wherein the step of inputting the periodic signal includes the step of converting an analog periodic signal to a digital periodic signal, while the following steps are performed by digital processing.

5. A method of measurement of a periodic signal as set forth in claim 2, further including, before step of applying a discrete Fourier transform, processing for multiplying a window function with a digitally converted periodic signal.

6. A method of measurement of a periodic signal as set forth in claim 2, wherein, at said step of calculating the maximum value and minimum value, said center part is a time-wise center part of the waveform corresponding to one cycle's worth of the input signal when substantially equally dividing the reconstructed time domain waveform into a head part, center part, and tail part.

7. A method of measurement of a periodic signal as set forth in claim 2, wherein said harmonic components are the n-th harmonics (n being an integer greater than or equal to 2) whose frequencies are multiples of the fundamental frequency, and the step of reconstructing the time domain waveform adds the harmonic frequency components to the fundamental frequency component up to a predetermined n-th order.

8. A method of measurement of a periodic signal as set forth in claim 7, wherein the order of the harmonic is determined using the value of “n” where the error between the waveform of the periodic signal and the waveform of the time domain reconstructed converges to substantially zero, when increasing “n”.

9. A method of testing a magnetic head comprising, using the method of measurement of amplitude of a periodic signal set forth in claim 1 or 2 to measure the + side amplitude and − side amplitude of the periodic read back signal from a magnetic head.

10. A method of testing a magnetic head as set forth in claim 9, further comprising judging symmetry or asymmetry of the periodic read back signal from the magnitudes of the + side amplitude and − side amplitude.

11. An apparatus for measurement of amplitude of a periodic signal comprising:
an AD conversion unit converting a periodic signal repeating a certain waveform periodically to a digital signal,
a discrete Fourier transform unit calculating magnitudes and phases of a fundamental frequency component and harmonic frequency components of the digital periodic signal in the frequency domain,
an inverse discrete Fourier transform unit applying an inverse discrete Fourier transform to the frequency components and summing the results to reconstruct the waveform in the time domain, and
an amplitude calculation unit calculating the amplitude of the periodic signal from the waveform data at the center part of the reconstructed waveform on the time axis.

12. An apparatus for measurement of amplitude of a periodic signal comprising:
an input unit inputting a periodic signal repeating a certain waveform periodically,
a frequency setting unit setting the closest discrete frequencies to the frequencies of a fundamental and harmonic frequency components of the periodic signal in the discrete frequency domain,
a discrete Fourier transform unit which calculates the fundamental frequency component and harmonic frequency components corresponding to the set discrete frequencies by a discrete Fourier transform,
an inverse Fourier transform unit applying an inverse Fourier transform to the frequency components and summing the results to reconstruct the waveform in the time domain, and
an amplitude calculation unit calculating the amplitude of the periodic signal based on the waveform data at the center part on the time domain.

13. An apparatus for measurement of amplitude of a periodic signal as set forth in claim 12, wherein the input unit includes an AD conversion unit for converting the periodic signal to a digital signal and a memory for holding the output of the AD conversion unit.

14. An apparatus for measurement of amplitude of a periodic signal as set forth in claim 12, further provided with a window function processing unit multiplying a window function with the signal applied from the input unit to the discrete Fourier transform unit.

15. An apparatus for testing a magnetic head using an apparatus for measurement of a periodic signal as set forth in claim 11 or 12 to measure a + side amplitude and − side amplitude of a periodic read back signal from a magnetic head, which measurement is a part of an evaluation of characteristics of magnetic heads.
